(19) United States
(12) Patent Application Publication
(10) Pub. No.: US 2025/0365955 A1
(43) Pub. Date: Nov. 27, 2025

(54) FABRICATION METHOD OF MEMORY DEVICE

(71) Applicant: Yangtze Memory Technologies Co., Ltd., Wuhan (CN)

(72) Inventors: Hao ZHANG, Wuhan (CN); Gang ZHANG, Wuhan (CN); Kuan DONG, Wuhan (CN); Meng XIAO, Wuhan (CN); Longdong LIU, Wuhan (CN); Zongliang HUO, Wuhan (CN)

(21) Appl. No.: 18/889,203

(22) Filed: Sep. 18, 2024

(30) Foreign Application Priority Data
May 22, 2024 (CN) 202410654994.2

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

Memory device and fabrication methods of such memory devices are provided. In one aspect, a fabrication method includes: forming a first stack structure including first gate layers and first dielectric layers stacked alternately; forming a second stack structure including second gate layers and second dielectric layers stacked alternately; forming a first connection structure located on a side of the first stack structure and the second stack structure along a second direction and is connected with at least one of the first gate layers and at least one of the second gate layers; and forming a bit line located between the first stack structure and the second stack structure.

### CROSS-REFERENCE TO RELATED APPLICATIONS

This application claims the benefit of priority to Chinese Patent Application No. 202410654994.2, filed on May 22, 2024, the disclosure of which is hereby incorporated by reference in its entirety.

### TECHNICAL FIELD

The present disclosure relates to the technical field of semiconductor chips, and particularly to a fabrication method of a memory device.

### BACKGROUND

As the feature size of memory cells approaches the lower limit of process, planar process and manufacturing technology has become challenging and costly, which leads to the storage density of 2D or planar NAND flash memory approaching the upper limit.

In order to overcome the limitations caused by the 2D or planar NAND flash memory, the industry has developed a memory with a three-dimensional structure (3D NAND), in which memory cells are in three-dimensional arrangement on a substrate to increase the storage density.

### SUMMARY

Examples of the present disclosure provide a fabrication method of a memory device.

The examples of the present disclosure comprise the following technical solutions:

In an aspect, some examples of the present disclosure provide a fabrication method of a memory device, comprising: forming a first stack structure comprising a plurality of first gate layers and a plurality of first dielectric layers stacked alternately along a first direction; forming a second stack structure comprising a plurality of second gate layers and a plurality of second dielectric layers stacked alternately along the first direction, wherein the second stack structure and the first stack structure are stacked along the first direction; forming a first connection structure that is located on a side of the first stack structure and the second stack structure along a second direction and is connected with at least one of the plurality of first gate layers and at least one of the plurality of second gate layers, wherein the second direction intersects the first direction; and forming a bit line located between the first stack structure and the second stack structure, wherein an extending direction of the bit line intersects the first direction.

In some examples, forming the first stack structure comprises: forming a first deck structure, wherein a first region of the first deck structure comprises a plurality of first sacrificial layers and a plurality of first dielectric layers stacked alternately along the first direction and adjoins a second region of the first deck structure, the second region of the first deck structure is located on a side of the first region of the first deck structure along the second direction, and the second direction intersects the first direction; forming the second stack structure comprises: forming a second deck structure located on a side of the bit line away from the first deck structure, wherein a first region of the second deck structure comprises a plurality of second sacrificial layers and a plurality of second dielectric layers stacked alternately along the first direction and adjoins a second region of the second deck structure, and the second region of the second deck structure is located on a side of the first region of the second deck structure along the second direction; after forming the first deck structure and before forming the second deck structure, the fabrication method comprises: removing part of the first deck structure to form a first connection hole that is located in the second region of the first deck structure; after forming the second deck structure and before forming the first connection structure, the fabrication method comprises: removing part of the second deck structure to form a second connection hole that is located in the second region of the second deck structure, wherein the second connection hole and the first connection hole jointly constitute a connection hole; after forming the second deck structure and before forming the first connection structure, the fabrication method further comprises: replacing the first sacrificial layers with the first gate layers, and replacing the second sacrificial layers with the second gate layers; and forming the first connection structure comprises: depositing a conductive material in the connection hole to form the first connection structure.

In some examples, after forming the first deck structure and before removing part of the first deck structure, the fabrication method further comprises: forming a first groove that is located in the second region of the first deck structure and extends through part of the first deck structure along the first direction, wherein the second region of the first deck structure comprises a plurality of third dielectric layers and a plurality of fourth dielectric layers stacked alternately along the first direction, and at least one of the plurality of third dielectric layers is connected with the first sacrificial layer; forming a first connection sacrificial layer that covers a bottom of the first groove and is in contact with the third dielectric layer; and forming a first isolation layer that is located in the first groove.

In some examples, forming the first connection sacrificial layer comprises: forming a first isolation sub-layer that covers a wall of the first groove; depositing a dielectric material in the first groove, wherein the dielectric material covers the bottom of the first groove; and performing ion implantation on the dielectric material to form the first connection sacrificial layer; and forming the first isolation layer comprises: forming a second isolation sub-layer in the first groove, wherein the second isolation sub-layer and the first isolation sub-layer jointly constitute the first isolation layer.

In some examples, removing part of the first deck structure comprises: removing the first isolation layer, the first connection sacrificial layer, and the plurality of third dielectric layers and the plurality of fourth dielectric layers that are stacked together, to form the first connection hole.

In some examples, after forming the second deck structure and before removing part of the second deck structure, the fabrication method further comprises: forming a second groove that is located in the second region of the second deck structure and extends through part of the second deck structure along the first direction, wherein the second region of the second deck structure comprises a plurality of fifth dielectric layers and a plurality of sixth dielectric layers stacked alternately along the first direction, and at least one of the plurality of fifth dielectric layers is connected with the second sacrificial layer; forming a second connection sacrificial layer that covers a bottom of the second groove and is in contact with the fifth dielectric layer; and forming a second isolation layer that is located in the second groove; and removing part of the second deck structure comprises: removing the second isolation layer, the second connection sacrificial layer, and the plurality of fifth dielectric layers and the plurality of sixth dielectric layers that are stacked together, to form the second connection hole.

In some examples, forming the first connection structure in the connection hole comprises: removing the first connection sacrificial layer and the second connection sacrificial layer to form a first recessed space and a second recessed space, wherein the first recessed space and the first connection hole are connected, and the second recessed space and the second connection hole are connected; removing the third dielectric layers exposed to the first recessed space and the fifth dielectric layers exposed to the second recessed space, to form a first filling space and a second filling space, wherein the first filling space and the first recessed space are connected, and the second filling space and the second recessed space are connected; and filling a conductive material in the connection hole to form the first connection structure.

In some examples, removing the first connection sacrificial layer and the second connection sacrificial layer further comprises: removing part of the third dielectric layers and part of the fifth dielectric layers to form a third recessed space and a fourth recessed space, wherein the third recessed space and the first connection hole are connected, and the fourth recessed space and the second connection hole are connected; and forming a third isolation layer in the third recessed space, and forming a fourth isolation layer in the fourth recessed space.

In some examples, after forming the first deck structure and before removing part of the first deck structure, the fabrication method further comprises: forming a third groove that is located in the second region of the first deck structure and extends through part of the first deck structure along the first direction, wherein the second region of the first deck structure comprises a plurality of third dielectric layers and fourth dielectric layers stacked alternately along the first direction, and at least one of the plurality of third dielectric layers is connected with the first sacrificial layer; forming a first isolation sub-layer that covers a wall of the third groove; forming a second isolation sub-layer, wherein the second isolation sub-layer covers a bottom of the third groove, is in contact with the third dielectric layer, and covers a side of the first isolation sub-layer; and forming a third isolation sub-layer in the third groove, wherein the third isolation sub-layer covers the second isolation sub-layer, and the first isolation sub-layer, the second isolation sub-layer and the third isolation sub-layer jointly constitute a first isolation layer.

In some examples, removing part of the first deck structure comprises: removing the second isolation sub-layer, the third isolation sub-layer, the plurality of third dielectric layers and the plurality of fourth dielectric layers to form the first connection hole.

In some examples, after forming the second deck structure and before removing part of the second deck structure, the fabrication method further comprises: forming a fourth groove that is located in the second region of the second deck structure and extends through part of the second deck structure along the first direction, wherein the second region of the second deck structure comprises a plurality of fifth dielectric layers and a plurality of sixth dielectric layers stacked alternately along the first direction, and at least one of the plurality of fifth dielectric layers is connected with the second sacrificial layer; forming a fourth isolation sub-layer that covers a wall of the fourth groove; forming a fifth isolation sub-layer that covers a bottom of the fourth groove and the fourth isolation sub-layer and is in contact with the fifth dielectric layer; and forming a sixth isolation sub-layer in the fourth groove, wherein the sixth isolation sub-layer covers the fifth isolation sub-layer, and the fourth isolation sub-layer, the fifth isolation sub-layer and the sixth isolation sub-layer jointly constitute a second isolation layer; and removing part of the second deck structure comprises: removing the fifth isolation sub-layer, the sixth isolation sub-layer, the plurality of fifth dielectric layers and the plurality of sixth dielectric layers to form the second connection hole.

In some examples, forming the first connection structure in the connection hole comprises: removing the second isolation sub-layer at the bottom of the third groove and the fifth isolation sub-layer at the bottom of the fourth groove to form a fifth recessed space and a sixth recessed space, wherein the fifth recessed space and the first connection hole are connected, and the sixth recessed space and the second connection hole are connected; removing the third dielectric layers exposed to the fifth recessed space and the fifth dielectric layers exposed to the sixth recessed space, to form a third filling space and a fourth filling space, wherein the third filling space and the fifth recessed space are connected, and the fourth filling space and the sixth recessed space are connected; and filling a conductive material in the connection hole to form the first connection structure.

In some examples, removing the second isolation sub-layer at the bottom of the third groove and the fifth isolation sub-layer at the bottom of the fourth groove comprises: removing part of the second dielectric layers and part of the fourth dielectric layers to form a seventh recessed space and an eighth recessed space, wherein the seventh recessed space and the first connection hole are connected, and the eighth recessed space and the second connection hole are connected; and forming a third isolation layer in the seventh recessed space, and forming a fourth isolation layer in the eighth recessed space.

In some examples, removing part of the first deck structure to form the first connection hole further comprises: forming a first gate slit that is located in the first region of the first deck structure; removing part of the second deck structure to form the second connection hole further comprises: forming a second gate slit that is located in the first region of the second deck structure, wherein the second gate slit and the first gate slit jointly constitute a gate slit; and replacing the first sacrificial layers with the first gate layers and replacing the second sacrificial layers with the second gate layers comprises: injecting an etchant into the gate slit to remove the first sacrificial layers and the second sacrificial layers, to form a fifth filling space and a sixth filling space; and depositing a gate material in the fifth filling space and the sixth filling space to form the first gate layers and the second gate layers.

In some examples, forming the first deck structure comprises: forming a first deck sub-structure that comprises a first gate sub-slit and a first channel hole; forming an etching stop layer on the first gate sub-slit and the first channel hole; and forming a second deck sub-structure that is located on a side of the etching stop layer away from the first gate sub-slit and the first channel hole, wherein the second deck sub-structure and the first deck sub-structure jointly constitute the first deck structure; and removing part of the first deck structure to form the first connection hole comprises: forming a second gate sub-slit and a second channel hole, wherein the second gate sub-slit and the first gate sub-slit jointly constitute the first gate slit, the second channel hole and the first channel hole jointly constitute a channel hole, and the first gate slit and the channel hole are located in the first region of the first deck structure.

In another aspect, some examples of the present disclosure further provide a fabrication method of a memory device, comprising: forming a first stack structure comprising a plurality of first gate layers and a plurality of first dielectric layers stacked alternately along a first direction; forming a second stack structure comprising a plurality of second gate layers and a plurality of second dielectric layers stacked alternately along the first direction, wherein the second stack structure and the first stack structure are stacked along the first direction; and forming a first connection structure, the first connection structure comprising a connection pillar, at least one first connection layer and at least one second connection layer, wherein the connection pillar is located on a side of the first stack structure and the second stack structure along a second direction; the first connection layer is parallel to the second direction; one first connection layer is connected with the connection pillar and one of the plurality of first gate layers; the second connection layer is parallel to the second direction; one second connection layer is connected with the connection pillar and one of the plurality of second gate layers; and the second direction intersects the first direction.

In some examples, forming the first stack structure comprises: forming a first deck structure, wherein a first region of the first deck structure comprises a plurality of first sacrificial layers and a plurality of first dielectric layers stacked alternately along the first direction and adjoins a second region of the first deck structure, the second region of the first deck structure is located on a side of the first region of the first deck structure along the second direction, and the second direction intersects the first direction; forming the second stack structure comprises: forming a second deck structure, wherein the second deck structure and the first deck structure are stacked along the first direction; a first region of the second deck structure comprises a plurality of second sacrificial layers and a plurality of second dielectric layers stacked alternately along the first direction; the first region of the second deck structure adjoins a second region of the second deck structure; and the second region of the second deck structure is located on a side of the first region of the second deck structure along the second direction; after forming the first deck structure and before forming the second deck structure, the fabrication method further comprises: removing part of the first deck structure to form a first connection hole that is located in the second region of the first deck structure; removing part of the second deck structure to form a second connection hole that extends through the second region of the second deck structure, wherein the second connection hole and the first connection hole jointly constitute a connection hole; forming a first filling space and a second filling space, wherein the first filling space is located in the second region of the first deck structure, the first filling space and the first connection hole are connected, the second filling space is located in the second region of the first deck structure, and the second filling space and the second connection hole are connected; and replacing the first sacrificial layers with the first gate layers, and replacing the second sacrificial layers with the second gate layers; and forming the first connection structure comprises: filling a conductive material in the connection hole to form the first connection structure, wherein the conductive material filled in the connection hole forms the connection pillar; the conductive material filled in the first filling space forms the first connection layer; the conductive material filled in the second filling space forms the second connection layer; the first connection layer is parallel to the second direction; one first connection layer is connected with the connection pillar and one of the plurality of first gate layers; the second connection layer is parallel to the second direction; one second connection layer is connected with the connection pillar and one of the plurality of second gate layers; and the connection pillar, the first connection layer and the second connection layer jointly constitute the first connection structure.

In yet another aspect, some examples of the present disclosure further provide a fabrication method of a memory device, comprising: forming a first deck structure, wherein a first region of the first deck structure comprises a plurality of first sacrificial layers and a plurality of first dielectric layers stacked alternately along the first direction and adjoins a second region of the first deck structure, the second region of the first deck structure is located on a side of the first region of the first deck structure along the second direction, and the second direction intersects the first direction; forming a first select gate that is located in the first region of the first deck structure; forming a bit line in the first region of the first deck structure, wherein the bit line is connected with the first select gate, and an extending direction of the bit line intersects the first direction; forming a second select gate that is located on a side of the bit line facing away from the first select gate and is connected with the bit line; and forming a second deck structure located on a side of the second select gate away from the first deck structure, wherein a first region of the second deck structure comprises a plurality of second sacrificial layers and a plurality of second dielectric layers stacked alternately along the first direction and adjoins a second region of the second deck structure, and the second region of the second deck structure is located on a side of the first region of the second deck structure along the second direction.

In some examples, after forming the first deck structure and before forming the second deck structure, the fabrication method further comprises: removing part of the first deck structure to form a first connection hole that is located in the second region of the first deck structure; after forming the second deck structure, the fabrication method further comprises: removing part of the second deck structure to form a second connection hole that is located in the second region of the second deck structure, wherein the second connection hole and the first connection hole jointly constitute a connection hole; replacing the first sacrificial layers with the first gate layers, and replacing the second sacrificial layers with the second gate layers; and forming a first connection structure in the connection hole, wherein the first connection structure is connected with at least one of the first gate layers and is connected with at least one of the second gate layers.

### BRIEF DESCRIPTION OF THE DRAWINGS

In order to illustrate the technical solutions in the present disclosure more clearly, the drawings to be used in some examples of the present disclosure will be briefly introduced below. Apparently, the drawings in the following description are only drawings of some examples of the present disclosure. Those of ordinary skills in the art may also obtain other drawings according to these drawings. In addition, the drawings in the following description may be regarded as schematic diagrams, instead of limitations to actual size of product, actual flow of method, actual timing of signal, etc. involved in the examples of the present disclosure.

FIG. 1 is a block diagram of an electronic apparatus according to some examples;

FIG. 2 is a block diagram of a memory system according to some examples;

FIG. 3 is a block diagram of a memory system according to some other examples;

FIG. 4 is a perspective schematic structural diagram of a memory device according to some examples;

FIG. 5 is a cross-sectional view of a memory device according to some examples;

FIG. 6 is a cross-sectional view of one memory cell string in the memory device shown in FIG. 4 along a sectional line AA′;

FIG. 7 is an equivalent circuit diagram of the memory cell string of FIG. 6;

FIG. 8 is a circuit diagram of a memory device according to some examples;

FIG. 9 is a schematic structural diagram of a memory device according to some examples;

FIG. 10 is a schematic structural diagram of a memory device according to some other examples;

FIG. 11 is a schematic structural diagram of a memory device in a Y-Z cross-section according to some examples;

FIG. 12 is a schematic structural diagram of a memory device in a Y-Z cross-section according to some other examples;

FIGS. 13-15 are schematic structural diagrams of a memory device according to different examples;

FIG. 16 is a circuit diagram of a memory device according to some other examples;

FIG. 17 is a schematic structural diagram of a memory device according to some other examples;

FIG. 18 is a flow diagram of a fabrication method of a memory device according to some examples;

FIGS. 19-43 are schematic structural diagrams of a memory device in a fabrication process according to some examples;

FIG. 44 is a flow diagram of a fabrication method of a memory device according to some other examples;

FIG. 45 is a flow diagram of a fabrication method of a memory device according to some other examples; and

FIG. 46 is a schematic structural diagram of a memory device in a fabrication process according to some other examples.

Reference numerals: 10 Memory device; 100 Peripheral device; 110 Substrate; 120 Transistor; 130 Peripheral interconnection layer; 200 Semiconductor structure; 300 Array interconnection layer; 400 Memory cell string; 500 Adhesion interface; 210 First stack structure; 211 First gate layer; 212 First dielectric layer; 2101 First stack sub-structure; 2102 Second stack sub-structure; 2103 First channel structure; 2104 Second channel structure; 220 Second stack structure; 221 Second gate layer; 222 Second dielectric layer; 230 First connection structure; 231 First connection sub-portion; 2311 First connection pillar; 2312 First connection layer; 3121 First sub-layer; 3122 Second sub-layer; 232 Second connection sub-portion; 2321 Second connection pillar; 2322 Second connection layer; 233 First isolation layer; 2331 First isolation sub-layer; 2332 Second isolation sub-layer; 2333 Third isolation sub-layer; 234 Second isolation layer; 2341 Fourth isolation sub-layer; 2342 Fifth isolation sub-layer; 2343 Sixth isolation sub-layer; 235 Third isolation layer; 236 Fourth isolation layer; 237 Connection pillar; BL Bit line; BL-1 First bit line; BL-2 Second bit line; 240 Second connection structure; 101 First region; 1011 First sub-region; 1012 Second sub-region; 102 Second region; 600 Semiconductor layer; 250 Third connection layer; 261 First select gate; 262 Second select gate; 263 Third select gate; 264 Fourth select gate; 270 Third stack structure; 271 Third dielectric layer; 272 Fourth dielectric layer; 280 Fourth stack structure; 281 Fifth dielectric layer; 282 Sixth dielectric layer; 290 Second connection structure; 710 First deck structure; 7101 First deck sub-structure; 7102 Second deck sub-structure; 711 First sacrificial layer; 712 First connection hole; 713 First groove; 714 First connection sacrificial layer; 715 First recessed space; 716 First filling space; 717 Third recessed space; 718 Third groove; 719 Fifth recessed space; 720 Second deck structure; 721 Second sacrificial layer; 722 Second connection hole; 723 Second groove; 724 Second connection sacrificial layer; 725 Second recessed space; 726 Second filling space; 727 Fourth recessed space; 728 Fourth groove; 729 Sixth recessed space; 730 Connection hole; 741 Seventh recessed space; 742 Eighth recessed space; 743 First gate slit; 7431 First gate sub-slit; 7432 Second gate sub-slit; 744 Second gate slit; 745 Third filling space; 746 Fourth filling space; 747 Fifth filling space; 748 Sixth filling space; 749 Etching stop layer; 750 Channel hole; 751 First channel hole; 752 Second channel hole; 760 Gate slit; 770 Isolation dielectric layer.

### DETAILED DESCRIPTION

The technical solutions in some examples of the present disclosure will be described below clearly and completely in conjunction with the drawings. Apparently, the examples described are only part of, but not all of, the examples of the present disclosure. All other examples obtained by those of ordinary skills in the art based on the examples provided by the present disclosure should fall into the scope of protection of the present disclosure.

In the description of the present disclosure, it is to be understood that the terms “center”, “upper”, “lower”, “front”, “rear”, “left”, “right”, “vertical”, “horizontal”, “top”, “bottom”, “inner”, “outer”, etc. indicate orientations or position relationships that are based on the orientations or position relationships as shown in the drawings, and are only intended to facilitate description of the present disclosure and to simplify the description, instead of indicating or implying that a device or an element indicated must have a specific orientation or be constructed and operated in a specific orientation, and thus cannot be interpreted as limiting the present disclosure.

Unless otherwise specified in the context, throughout the specification and the claims, the term “comprise” is interpreted as an open and inclusive meaning, i.e., “including, but not limited to”. In the description of the specification, the terms “one example”, “some examples”, “an example”, or “in an example”, etc. are intended to indicate that particular features, structures, materials, or characteristics related to the example are included in at least one example of the present disclosure. The schematic representation of the above terms may not necessarily refer to the same example. Furthermore, these particular features, structures, materials, or characteristics may be included in any one or more examples in any suitable manner.

In the following, the terms “first” and “second” are only for the purpose of description, and cannot be construed as indicating or implying relative importance or implicitly indicating the number of indicated technical features. Thus, features defined by “first” and “second” may explicitly or implicitly include one or more of such features. In the description of the examples of the present disclosure, “a plurality of” means two or more, unless otherwise stated.

In describing some examples, the expressions “coupled” and “connected” and derivatives thereof may be used. For example, the term “connected” may be used in the description of some examples to indicate that two or more components have a direct physical contact or an electrical contact with each other. For another example, the term “coupled” may be used in the description of some examples to indicate that two or more components have a direct physical contact or an electrical contact. However, the term “coupled” may also mean that two or more components have no direct contact with each other, but still cooperate or interact with each other. The examples disclosed herein are not necessarily limited to the content herein.

“At least one of A, B and C” and “at least one of A, B or C” have the same meaning, both including the following combinations of A, B and C: A alone, B along, C alone, a combination of A and B, a combination of A and C, a combination of B and C, and a combination of A, B and C.

“A and/or B” includes the following three combinations: A alone, B alone, and a combination of A and B.

The use of “suitable for” or “configured to” herein means open and inclusive language, and does not exclude an apparatus suitable for performing or configured to perform additional tasks or operations.

In addition, the use of “based on” means openness and inclusiveness, as processes, steps, calculations, or other actions “based on” one or more of the described conditions or values may be based on an additional condition or exceed the described value in practice.

As used herein, “about”, “approximately” or “near” includes a value set forth and an average value within an acceptable deviation range of a specific value, wherein the acceptable deviation range is determined by a measurement being discussed or an error (i.e., a limitation of a measurement system) related to a measurement of a specific quantity, as considered by those of ordinary skills in the art.

The meaning of “on”, “above”, and “over” in the contents of the present disclosure should be interpreted in the broadest manner such that “on” not only means “directly on something” but also includes the meaning of “on something” with an intermediate feature or layer therebetween, and that “above” or “over” not only means “above” or “over” something but also includes the meaning of “above” or “over” something without intermediate feature or layer therebetween (i.e., directly on something).

Example implementations are described herein with reference to a cross-sectional view and/or a planar view that are used as idealized example drawings. In the drawings, thicknesses of a layer and a region are exaggerated for clarity. Thus, changes in shapes relative to the drawings caused by, for example, a manufacturing technology and/or a tolerance, may be contemplated. Therefore, the example implementations should not be interpreted as being limited to the shapes of regions shown herein, but rather comprise shape deviations caused by, for example, manufacturing. For example, an etching region shown as a rectangle will typically have a curved feature. Therefore, the regions shown in the drawings are essentially schematic, and their shapes are neither intended to show actual shapes of regions of an apparatus, nor intended to limit the scope of the example implementations.

As used herein, the term “substrate” refers to a material onto which subsequent material layers may be added. The substrate itself can be patterned. Materials added onto the substrate can be patterned or can remain unpatterned. Furthermore, the substrate may include a variety of semiconductor materials, such as silicon, germanium, gallium arsenide, indium phosphide, etc. Alternatively, the substrate can be made from an electrically non-conductive material, such as a glass, a plastic, or a sapphire wafer, etc.

Some examples of the present disclosure provide an electronic apparatus. FIG. 1 is a block diagram of an electronic apparatus according to some examples. As shown in FIG. 1, the electronic apparatus 3000 comprises a mainboard 2000 and a memory system 1000, wherein the mainboard 2000 is connected with the memory system 1000. In addition, the electronic apparatus 3000 may also comprise at least one of a Central Processing Unit (CPU) and a cache, etc.

In an example, the electronic apparatus 3000 may be any one of a cellphone, a desktop computer, a tablet computer, a notebook computer, a server, a vehicle apparatus, a wearable apparatus (e.g., a smart watch, a smart bracelet, and smart glasses, etc.), a mobile power bank, a gaming console, and a digital multimedia player, etc.

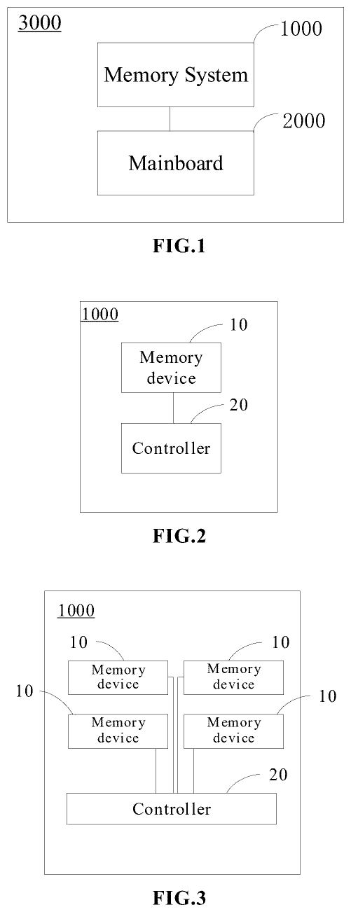

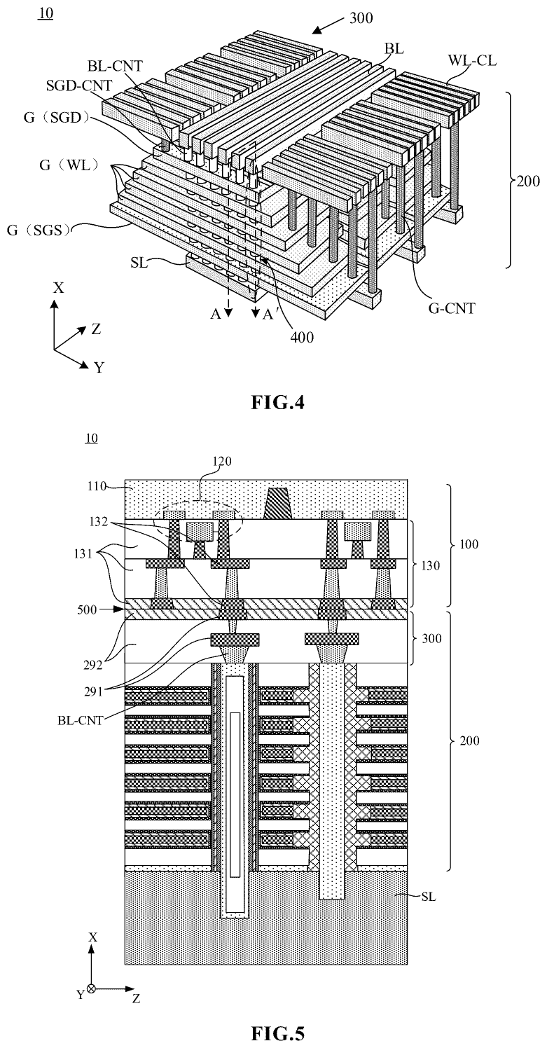

FIG. 2 is a block diagram of a memory system according to some examples. FIG. 3 is a block diagram of a memory system according to some other examples.

Referring to FIGS. 2 and 3, some examples of the present disclosure further provide a memory system 1000. The memory system 1000 comprises a controller 20 and a memory device 10. The controller 20 is coupled with the memory device 10 to control the memory device 10 to store data.

The memory system 1000 may be integrated into various types of storage apparatuses, for example, be included in the same package, such as a universal flash storage (UFS) package or an embedded multi media card (eMMC) package. That is to say, the memory system 1000 can be applied to and packaged into different types of electronic products, for example, a mobile phone (e.g. a cellphone), a desktop computer, a tablet computer, a laptop computer, a server, a vehicle apparatus, a game console, a printer, a positioning apparatus, a wearable apparatus, a smart sensor, a mobile power bank, a virtual reality (VR) apparatus, an augmented reality (AR) apparatus or any other suitable electronic apparatuses having memories therein.

In some examples, with reference to FIG. 2, the memory system 1000 comprises a controller 20 and one memory device 10, and may be integrated into a memory card. In an example, the memory device 10 may be a memory (3D NAND) having a three-dimensional structure.

The memory card includes any one of a PC (PCMCIA, Personal Computer Memory Card International Association) card, a Compact Flash (CF) card, a Smart Media (SM) card, a memory stick, a Multimedia Card (MMC), a Secure Digital Memory Card (SD) card, and a UFS.

In some other examples, with reference to FIG. 3, the memory system 1000 comprises a controller 20 and a plurality of memory devices 10, and is integrated into a solid state drive (SSD).

In some examples, in the memory system 1000, the controller 20 is configured for operating in a low duty-cycle environment, such as a SD card, a CF card, a Universal Serial Bus (USB) flash drive, or other media for use in electronic apparatuses, such as a personal computer, a digital camera, a mobile phone, etc.

In some other examples, the controller 20 is configured for operating in high duty-cycle environment SSDs or eMMCs used as data memories for mobile apparatuses, such as smartphones, tablet computers, notebook computers, etc., and enterprise memory arrays.

In some examples, the controller 20 may be configured to manage the data stored in the memory devices 10 and communicate with an external apparatus (e.g., a host). In some examples, the controller 20 may be further configured to control operations of the memory devices 10, such as read, erase, and program operations. In some examples, the controller 20 may be further configured to manage various functions with respect to data stored or to be stored in the memory devices 10, including at least one of bad-block management, garbage collection, logical-to-physical address conversion, and wear leveling. In some examples, the controller 20 is further configured to process error correction codes with respect to the data read from or written to the memory devices 10.

Of course, the controller 20 may also perform any other suitable functions, such as formatting the memory devices 10. For example, the controller 20 may communicate with an external apparatus (e.g., a host) through at least one of various interface protocols.

It is to be noted that, the interface protocols include at least one of a USB protocol, an MMC protocol, a Peripheral Component Interconnection (PCI) protocol, a PCI-Express (PCI-E) protocol, an Advanced Technology Attachment (ATA) protocol, a serial-ATA protocol, a parallel-ATA protocol, a Small Computer Small Interface (SCSI) protocol, an Enhanced Small Disk Interface (ESDI) protocol, an Integrated Drive Electronics (IDE) protocol, and a Firewire protocol.

The controller 20 in the above examples may be, for example, a central processing unit (CPU), a general-purpose processor, a digital signal processor (DSP), an application-specific integrated circuit (ASIC), a field programmable gate array (FPGA), or other programmable logic devices, transistor logic devices, hardware components, or any combination thereof.

Some examples of the present disclosure provide a memory device 10. The memory device 10 may be applied in the above-mentioned memory system 1000. Of course, the memory device 10 may be also applied in other memory systems, on which the present disclosure has no limitation.

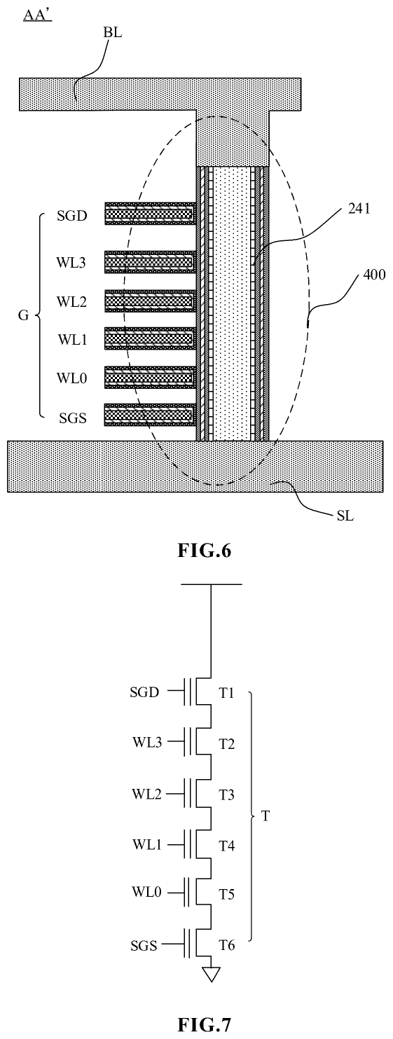

FIG. 4 is a perspective schematic structural diagram of a memory device according to some examples. FIG. 5 is a cross-sectional view of a memory device according to some examples. FIG. 6 is a cross-sectional view of one memory cell string in the memory device of FIG. 4 along a sectional line AA′. FIG. 7 is an equivalent circuit diagram of the memory cell string of FIG. 6.

It is to be noted that, in FIGS. 4 and 5, a first direction X and a second direction Y may be two intersected directions, and a third direction Z may intersect an X-Y plane. The present disclosure explains and illustrates a semiconductor structure 200 by taking the second direction Y and the third direction Z being two orthogonal directions in a plane where the semiconductor structure 200 is located (e.g., a plane where the semiconductor layer is located) as an example: the second direction Y is, for example, an extending direction of a word line WL, the third direction is, for example, an extending direction of a bit line BL, and the first direction X is perpendicular to the two orthogonal directions in the plane where the semiconductor structure 200 is located, i.e., is perpendicular to the X-Y plane. The memory device 10 extends in a Y-Z plane.

As used in the present disclosure, whether a component (e.g., a layer, structure or device) is “on”, “above”, or “below” another component (e.g., a layer, structure or device) of a semiconductor device (e.g., a memory device) is determined in the first direction relative to a semiconductor layer of the semiconductor device when the semiconductor layer is located in a lowest plane of the semiconductor device in the first direction X. The same concept for describing a spatial relationship is applied throughout the present disclosure.

With reference to FIGS. 4 and 5, some examples of the present disclosure provide a memory device 10. The memory device 10 may comprise a semiconductor structure 200, and a peripheral device 100 coupled with the semiconductor structure 200. The peripheral device 100 may be disposed on a side of the semiconductor structure 200.

The semiconductor structure 200 may comprise a semiconductor layer. A composition material of the semiconductor layer may comprise, for example, monocrystalline, monocrystalline germanium, a group III-V compound semiconductor material, a group II-VI compound semiconductor material, and other semiconductor materials.

The semiconductor structure 200 may further comprise memory cell transistor strings 400 (which may be referred to as “memory cell strings” herein, for example, NAND memory cell strings) disposed in an array. The semiconductor layer may comprise a source layer SL that may be coupled with sources of the plurality of memory cell strings 400. In an example, the source layer SL may be doped partially or completely. For example, the source layer SL may comprise a doped region that is doped with a p-type dopant. The source layer may also comprise a non-doped region.

In an example, with reference to FIGS. 6 and 7, the memory cell string 400 may comprise a plurality of transistors T, one transistor T (e.g., T1-T6 in FIG. 7) may be disposed as one memory cell. These transistors T are connected together to form the memory cell string. A transistor T (e.g., each transistor T) may be formed by a channel structure 240 and a gate line G surrounding the channel structure 240. The gate line G is configured to control an on state of the transistor.

It is to be noted that, the number of the transistors in FIGS. 4-7 is simply schematic, and the memory cell string of the memory device provided by the examples of the present disclosure may also comprise other numbers of transistors, e.g., 4, 16, 32, and 64.

Further, the lowest one (e.g., one of the plurality of gate lines G closest to the source layer SL) of a plurality of gate lines G along the third direction Z is constructed as a source select gate SGS that is configured to control an on state of the transistor T6, which in turn controls an on state of a source channel in the memory cell string 400. The uppermost one (e.g., one of the plurality of gate lines farthest away from the source layer SL) of the plurality of gate lines G is constructed as a drain select gate SGD that is configured to control an on state of the transistor T1, which in turn controls an on state of a drain channel in the memory cell string 400. Middle ones of the plurality of gate lines G may be constructed as a plurality of word lines WL, for example, including a word line WL0, a word line WL1, a word line WL2, and a word line WL3. Data writing, reading and erasing of each memory cell (e.g., the transistor T) in the memory cell string 400 may be completed by writing different voltages to the word lines WL.

With continued reference to FIGS. 4 and 5, in some examples, the semiconductor structure 200 may further comprise an array interconnection layer 300. The array interconnection layer 300 may be coupled with the memory cell string 400. The array interconnection layer 300 may comprise a drain (i.e., the bit line BL) of the memory cell string 400, wherein the drain may be coupled with a semiconductor channel of each transistor T in at least one memory cell string 400.

The array interconnection layer 300 may comprise one or more first interlayer insulation layers 292, and may further comprise a plurality of contacts insulated from each other through these first interlayer insulation layers 292. The contacts include, for example, a bit line contact BL-CNT coupled with the bit line BL, a drain select gate contact SGD-CNT coupled with the drain select gate SGD, and a gate line contact G-CNT coupled with the gate line G. The array interconnection layer 300 may further comprise one or more first interconnection conductor layers 291. The first interconnection conductor layer 291 may comprise a plurality of connection lines, e.g., the bit line BL, and a word line connection line WL-CL coupled the word line WL. Materials of the first interconnection conductor layer 291 and the contact may include a conductive material, for example, one or a combination of tungsten, cobalt, copper, aluminum, and metal silicides, and may also include other conductive materials. A material of the first interlayer insulation layer 292 may include an insulation material, for example, one or a combination of silicon oxide, silicon nitride, and a high dielectric constant insulation material, and may also include other insulation materials.

The peripheral device 100 may comprise a peripheral circuit. The peripheral circuit is configured to control and sense an array device. The peripheral circuit may be any suitable digital, analog or hybrid signal control and sensing circuit for supporting operations (or working) of the array device, including, but not limited to, a page buffer, a decoder (e.g., a row decoder and a column decoder), a readout amplifier, a driver (e.g., a word line driver), a charge pump, a current or voltage reference, or any active or passive components (e.g., a transistor, a diode, a resistor or a capacitor) of a circuit. The peripheral circuit may further comprise any other circuits compatible with an advanced logic process, including a logic circuit, e.g., a processor and a programmable logic device (PLD), or memory circuit, e.g., a static random-access memory (SRAM).

In some examples, the peripheral device 100 may comprise a substrate 110, a transistor 120 disposed on the substrate 110, and a peripheral interconnection layer 130 disposed on the substrate 110. The peripheral circuit may comprise the transistor 120.

A material of the substrate 110 may include monocrystalline silicon, or other suitable materials, e.g., silicon germanium, germanium or a silicon thin film on insulator.

The peripheral interconnection layer 130 is coupled with the transistor 120 to achieve electrical signal transmission between the transistor 120 and the peripheral interconnection layer 130. The peripheral interconnection layer 130 may comprise one or more second interlayer insulation layers 131, and may further comprise one or more second interconnection conductor layers 132. Different second interconnection conductor layers 132 may be coupled through contacts. Materials of the second interconnection conductor layer 132 and the contacts may include a conductive material, for example, one or a combination of tungsten, cobalt, copper, aluminum, and metal silicides, or may also include other suitable materials. A material of the second interlayer insulation layer 131 may include an insulation material, for example, one or a combination of silicon oxide, silicon nitride, and a high dielectric constant insulation material, and may also include other suitable materials.

The peripheral interconnection layer 130 may be coupled with the array interconnection layer 300, such that the semiconductor structure 200 may be coupled with the peripheral device 100. In an example, since the peripheral interconnection layer 130 is coupled with the array interconnection layer 300, the peripheral circuit in the peripheral device 100 may be coupled with the memory cell string in the semiconductor structure 200, so as to achieve electrical signal transmission between the peripheral circuit and the memory cell string. In some possible implementations, an adhesion interface 500 may be disposed between the array interconnection layer 130 and the array interconnection layer 300, and the peripheral interconnection layer 130 may be adhered and coupled to the array interconnection layer 300 through the adhesion interface 500.

At present, users are pursuing memory devices with large capacity and small size. With continued reference to FIG. 4, in order to increase the capacity of the memory device, the number of stacked layers of the gate lines G is increasing. However, one gate line G is connected with one gate line contact G-CNT. As the number of layers of the gate lines G increases, the number of the gate line contacts G-CNT coupled with the gate lines G also increases, and thus the footprint of the gate line contact G-CNT increases, resulting in an increase of the size of the memory device in the second direction, which is unfavorable to increase the storage density of the memory device or to the development of the memory device towards a smaller size.

Moreover, the gate line G is coupled with a SD (String Driver) device through the gate line contact G-CNT. However, since one gate line contact G-CNT is connected with one SD device, as the number of the gate line contacts G-CNT increases, the number of the SD devices will also increase, and the footprint of the SD device will increase as well, which is unfavorable to the development of the memory device towards a smaller size.

In addition, as the number of stacked layers of the gate lines G increases, the number of the SD devices also increases. In order to control the size of the memory device, how to reduce the size of the SD device has become one of the problems to be solved in the art.

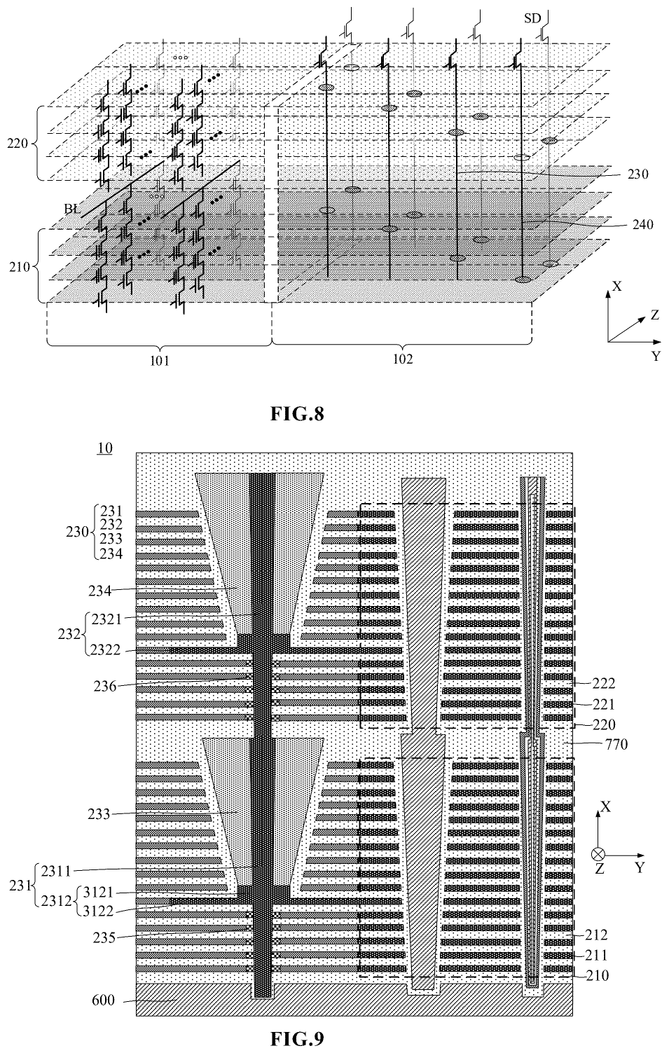

FIG. 8 is a circuit diagram of a memory device according to some examples. FIG. 9 is a schematic structural diagram of a memory device according to some examples. As shown in FIGS. 8 and 9, some examples of the present disclosure provide a memory device 10 that comprises a first stack structure 210, a second stack structure 220, a first connection structure 230 and a bit line BL.

The first stack structure 210 may be disposed on a semiconductor layer 600. In an example, the first stack structure 210 may be in direct contact with the semiconductor layer 600. In an example, a composition material of the semiconductor layer 600 may include, for example, monocrystalline silicon, monocrystalline germanium, a group III-V compound semiconductor material, a group II-VI compound, and other suitable semiconductor materials.

The first stack structure 210 comprises a plurality of first gate layers 211 and a plurality of first dielectric layers 212 stacked alternately along a first direction X. For example, first gate layers 211 and first dielectric layers 212 disposed alternately along the first direction X are stacked to form the plurality of first gate layers 211 and the plurality of first dielectric layers 212 spaced apart from each other. It may also be understood that, one first gate layer 211 and one first dielectric layer 212 jointly constitute one first gate structure pair, and the first stack structure 210 comprises a plurality of first gate structure pairs stacked along the first direction X.

In an example, the number of the first gate layers 211 and the first dielectric layers 212 may be 4, 16, 32, 64, 128, 256, or the like. The thickness (i.e., the size along the first direction X) of the first gate layer 211 is approximately equal to or may be different from the thickness of the first dielectric layer 212. For example, the thickness of the first dielectric layer 212 is greater than the thickness of the first gate layer 211.

In an example, the first gate layer 211 may comprise a conductive material that includes, but is not limited to, one or a combination of tungsten (W), cobalt (Co), copper (Cu), aluminum (Al), polysilicon, doped silicon, and silicides, or may be other suitable conductive materials. In some examples, the first gate layer 211 comprises a metal layer, e.g., a tungsten layer. In some examples, the first gate layer 211 comprises a doped polysilicon layer. The polysilicon may be doped to a desired doping concentration using a suitable dopant, such that the polysilicon may become a conductive material used for the first gate layer 211.

In an example, the first dielectric layer 212 may comprise an insulation material that may include one or a combination of silicon oxide, silicon nitride, silicon oxynitride and a high dielectric constant insulation material, or may be other suitable insulation materials. A dielectric constant of silicon oxynitride is higher than a dielectric constant of silicon oxide. For example, in an environment at about 20° C., the dielectric constant of silicon oxynitride is 4-7, for example, 3.8, 4, 4.8, 5.3, 5.9, 6, 6.36, 6.88, 7, 7.2, etc. In some examples, the first dielectric layer 212 comprises a silicon oxide layer. In some examples, the first dielectric layer 212 comprises a silicon oxynitride layer.

In an example, the thickness (i.e., the size along the first direction X) of the first gate layer 211 may be between 10 nm and 50 nm, for example, 10 nm, 15 nm, 18.3 nm, 20 nm, 25 nm, 27.7 nm, 30 nm, 35 nm, 40 nm, 45 nm, 50 nm, etc. Similarly, the thickness (i.e., the size along the first direction X) of the first dielectric layer 212 may be between 10 nm and 50 nm, for example, 10 nm, 15 nm, 18.3 nm, 20 nm, 25 nm, 27.7 nm, 30 nm, 35 nm, 40 nm, 45 nm, 50 nm, etc. The first gate layer 211 may be a gate line G surrounding the memory cell string (with reference to FIG. 6), and may extend laterally (i.e., along the second direction Y) as a word line WL (with reference to FIG. 4).

The second stack structure 220 comprises a plurality of second gate layers 221 and a plurality of second dielectric layers 222 stacked alternately along the first direction X, for example, second gate layers 221 and second dielectric layers 222 disposed alternately along the first direction X are stacked to form the plurality of second gate layers 221 and the plurality of second dielectric layers 222 spaced apart from each other.

It may be understood that, the composition material, thickness and number of the second gate layers 221 and the second dielectric layers 222 may be referred to the above examples of the composition material, thickness and number of the first gate layers 211 and the first dielectric layers 212. The composition material, thickness and number of the second gate layers 221 may be the same as or different from those of the first gate layer 211, and the composition material, thickness and number of the second dielectric layer 222 may be the same as or different from those of the first dielectric layer 212.

Moreover, as shown in FIG. 9, the second stack structure 220 and the first stack structure 210 are stacked along the first direction X. An isolation dielectric layer 770 is disposed between the first stack structure 210 and the second stack structure 220. In the first direction X, the thickness of the isolation dielectric layer 770 is much greater than the thickness of the first dielectric layer 212 (or the second dielectric layer 222). In an example, in the first direction X, the thickness of the isolation dielectric layer 770 may be 2-10 times of the thickness of the first dielectric layer 212. For example, in the first direction X, the thickness of the isolation dielectric layer 770 may be 2, 6 or 10 times of the thickness of the first dielectric layer 212. When the thickness of the isolation dielectric layer 770 approaches 2 times of the thickness of the first dielectric layer 212, the gap between the first stack structure 210 and the second stack structure 220 is small, which is favorable to increase the storage density of the memory device 10. When the thickness of the isolation dielectric layer 770 approaches 10 times of the thickness of the first dielectric layer 212, an isolation effect between the first stack structure 210 and the second stack structure 220 is enhanced.

A composition material of the isolation dielectric layer 770 may be the same as a composition material of the first dielectric layer 212 (or the second dielectric layer 222). In an example, a top layer (a layer in the first stack structure 210 closest to the second stack structure 220) of the first stack structure 210 may be the first dielectric layer 212. During the formation of the topmost first dielectric layer 212 in the first stack structure 210, the thickness of the topmost first dielectric layer 212 may be increased to isolate the first stack structure 210 from the second stack structure 220. Here, the thickened topmost first dielectric layer 212 may serve as the isolation dielectric layer 770 between the first stack structure 210 and the second stack structure 220. In an example, a bottom layer (a layer in the second stack structure 220 closest to the first stack structure 210) of the second stack structure 220 may be the second dielectric layer 222. During the formation of the bottommost second dielectric layer 222 in the second stack structure 220, the thickness of the bottommost second dielectric layer 222 may be increased to isolate the first stack structure 210 from the second stack structure 220. Here, the thickened bottommost second dielectric layer 222 may serve as the isolation dielectric layer 770 between the first stack structure 210 and the second stack structure 220.

In this example, as shown in FIGS. 8 and 9, the first connection structure 230 is located on a side of the first stack structure 210 and the second stack structure 220 along a second direction Y. In an example, the memory device 10 may comprise a first region 101 and a second region 102. In the second direction Y, the first region 101 adjoins the second region 102. Both the first stack structure 210 and the second stack structure 220 may be located in the first region 101, and the first connection structure 230 may be located in the second region 102.

The first connection structure 230 is used to connect the first gate layer 211 and an SD device, and to connect the second gate layer 221 and the SD device. In an example, a composition material of the first connection structure 230 may include a conductive material that includes, but is not limited to, one or a combination of tungsten (W), cobalt (Co), copper (Cu), aluminum (Al), polysilicon, doped silicon, and silicides, or may be also other suitable conductive materials.

Moreover, as shown in FIGS. 8 and 9, the first connection structure 230 is connected with at least one of the first gate layers 211 and is connected with at least one of the second gate layers 221. For example, in FIG. 9, the first connection structure 230 is connected with one of the first gate layers 211 in the first stack structure 210, and is connected with one of the second gate layers 221 in the second stack structure 220. An end of the first connection structure 230 away from the semiconductor layer 600 may be connected with the SD device that may be connected with at least one of the first gate layers 211 and at least one of the second gate layers 221 through the first connection structure 230.

It is to be noted that the first connection structure 230 being connected with at least one of the first gate layers 211 may be understood as that the first connection structure 230 may be connected with one of the first gate layers 211 or connected with the plurality of first gate layers 211. Moreover, the first connection structure 230 being connected with at least one of the second gate layers 221 may be understood as that the first connection structure 230 may be connected with one of the second gate layers 221 or connected with the plurality of second gate layers 221. In this example, the first connection structure 230 being connected with one of the first gate layers 211 and the first connection structure 230 being connected with one of the second gate layers 221 are illustrated as an example.

In some other examples, with reference to FIGS. 4, 8 and 9, one first gate layer 211 is connected with one SD device through one gate line contact G-CNT, one second gate layer 221 is connected with one SD device through one gate line contact G-CNT. There are numerous gate line contacts G-CNT and SD devices, and the plurality of gate line contacts G-CNT are in a staircase arrangement, resulting in a large footprint of the gate line contacts G-CNT and the SD devices, which is unfavorable to increase the storage density of the memory device 10.

However, in this example, with reference to FIGS. 8 and 9, one first gate layer 211 and one second gate layer 221 may share one first connection structure 230 and may share one SD device. Thus, when the memory device 10 has two stack structures (i.e., the first stack structure 210 and the second stack structure 220), compared with one first gate layer 211 being connected with one SD device through one gate line contact G-CNT and one second gate layer 221 being connected with one SD device through one gate line contact G-CNT, the number of the first connection structures 230 in this example is less than the number of the gate line contacts G-CNT, and the number of the SD devices in this example is also smaller, such that the footprint of the first connection structure 230 is smaller than the footprint of the gate line contact G-CNT, and meanwhile, the footprint of the SD device is also reduced, which is favorable to increase the storage density of the memory device 10.

When the memory device 10 comprises more stack structures, for example, the memory device 10 may comprise 4, 6, or 8 stack structures, or the like, at this point, the first connection structure 230 may be connected with one gate layer in each of the plurality of stack structures. With the above arrangement, even if more stack structures are added, the number of the first connection structures 230 will not increase, i.e., the footprint of the first connection structure 230 will not increase, which is favorable to increase the storage density of the memory device 10 and to the development of the memory device 10 towards a large capacity and a small size.

In addition, it has been mentioned above that the number of the stack structures is increasing and the number of the SD devices is also increasing in order to increase the capacity of the memory device 10 in the art. In order to control the size of the memory device 10, the problem of reducing the size of the SD device need to be addressed. The first connection structure 230 being connected with one gate layer in each of the plurality of stack structures in this example will not increase the number of the SD devices, and thus, the demand on reducing the size of the SD device may be reduced.

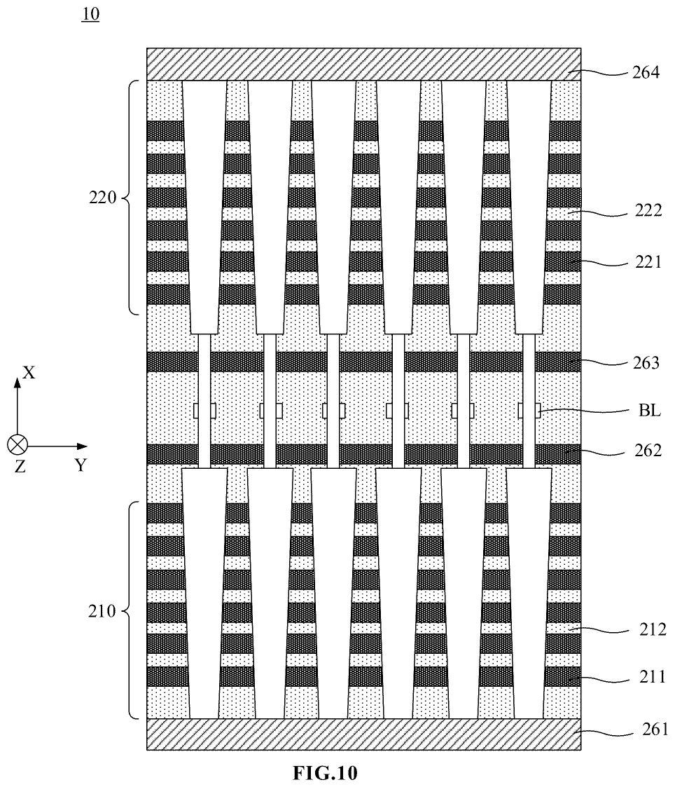

In this example, as shown in FIGS. 9 and 10, the bit line BL is located between the first stack structure 210 and the second stack structure 220, and an extending direction of the bit line BL intersects the first direction X. It may be understood that the bit line BL may extend in a Y-Z plane, for example, the extending direction of the bit line BL may be parallel to a third direction Z. There may be a plurality of bit lines BL spaced apart along the second direction Y. As shown in FIG. 10, the bit line BL is connected with a channel structure in the first stack structure 210, and is also connected with a channel structure in the second stack structure 220. With the above arrangement, the bit line BL is located between the first stack structure 210 and the second stack structure 220, and can drive the channel structure in the first stack structure 210 upwards, and meanwhile drive the channel structure in the second stack structure 220 downwards. In some other examples, when the bit line BL is located at topmost (an end of the second stack structure 220 away from the first stack structure 210) of the plurality of stack structures, due to the resistance in the channel structure, the current intensity in part of the channel structure away from the bit line BL is weak. Compared with the solution that the bit line BL is located at the topmost of the plurality of stack structures, in this example, the bit line BL is located between the first stack structure 210 and the second stack structure 220, which is favorable to increase the current intensity in the channel structure and solve the problem that the current intensity in part of the channel structure away from the bit line BL is weak.

In some examples, as shown in FIG. 9, the first connection structure 230 comprises a first connection sub-portion 231 and a second connection sub-portion 232 stacked along the first direction. The first connection sub-portion 231 comprises a first connection pillar 2311 and at least one first connection layer 2312. The first connection pillar 2311 extends along the first direction, the first connection layer 2312 is parallel to the second direction Y, and one first connection layer 2312 is connected with the first connection pillar 2311 and one first gate layer 211.

In an example, in the Y-Z plane, the first connection layer 2312 may surround the first connection pillar 2311, and be connected with the first connection pillar 2311. Moreover, the first connection pillar 2311 and the first connection layer 2312 may be disposed integrally. The first connection layer 2312 and one first gate layer 211 may be located on the same level (the Y-Z plane) to facilitate the connection of the first connection layer 2312 with one first gate layer 211.

It is to be noted that the first connection sub-portion 231 comprising at least one first connection layer 2312 may be understood as that the first connection sub-portion 231 may comprise one first connection layer 2312 or the first connection sub-portion 231 may comprise a plurality of first connection layers 2312. When the first connection sub-portion 231 comprises a plurality of first connection layers 2312, the plurality of first connection layers 2312 may be spaced apart along the first direction X. In this example, the first connection sub-portion 231 comprising one first connection layer 2312 is illustrated as an example.

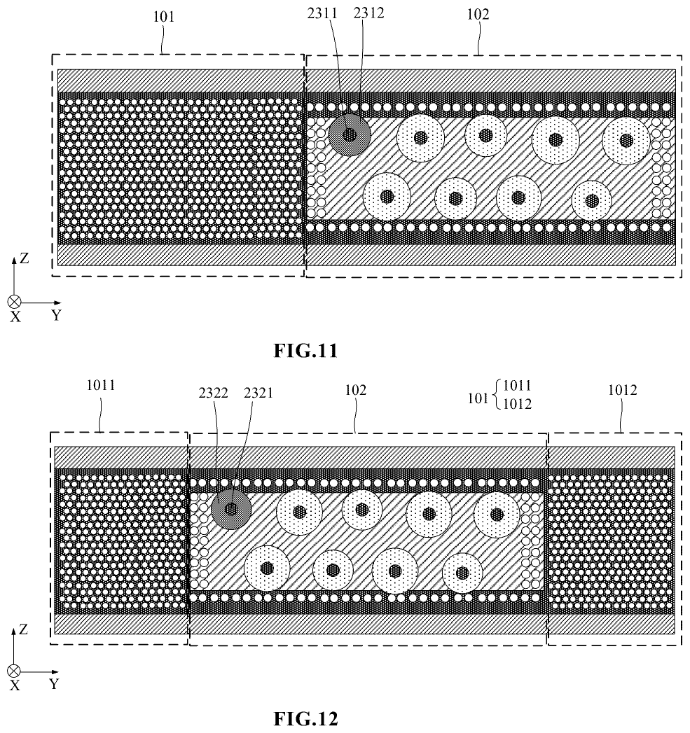

With reference to FIG. 11, in the Y-Z plane, the cross-section of the first connection pillar 2311 may be, e.g., circular, the cross-section of the first connection layer 2312 may be, e.g., ring-shaped, and the first connection layer 2312 may be disposed around the first connection pillar 2311, and is connected with the first connection pillar 2311.

The second connection sub-portion 232 comprises a second connection pillar 2321 and at least one second connection layer 2322. The second connection pillar 2321 extends along the first direction X, and is connected with the first connection pillar 2311. The second connection layer 2322 is parallel to the second direction Y, and one second connection layer 2322 is connected with the second connection pillar 2321 and one second gate layer 221.

In an example, with reference to FIGS. 9 and 12, in the Y-Z plane, the second connection layer 2322 may surround the second connection pillar 2321, and is connected with the second connection pillar 2321. The second connection pillar 2321 is connected with the first connection pillar 2311, and the first connection pillar 2311, the first connection layer 2312, the second connection pillar 2321 and the second connection layer 2322 may be disposed integrally. The second connection layer 2322 and one second gate layer 221 may be located on the same level (the Y-Z plane) to facilitate the connection of the second connection layer 2322 with one second gate layer 221.

It is to be noted that the second connection sub-portion 232 comprising at least one second connection layer 2322 may be understood as that the second connection sub-portion 232 may comprise one second connection layer 2322 or the second connection sub-portion 232 may comprise a plurality of second connection layers 2322. When the second connection sub-portion 232 comprises a plurality of second connection layers 2322, the plurality of second connection layers 2322 may be spaced apart along the first direction X. In this example, the first connection sub-portion 231 comprising one first connection layer 2312 is illustrated as an example.

With reference to FIG. 12, in the Y-Z plane, the cross-section of the second connection pillar 2321 may be, e.g., circular, the cross-section of the second connection layer 2322 may be, e.g., ring-shaped, and the second connection layer 2322 may be disposed around the second connection pillar 2321, and is connected with the second connection pillar 2321.

With the above arrangement, an end of the second connection pillar 2321 away from the first connection pillar 2311 may be connected with the SD device, one SD device may be connected with at least one second gate layer 221 through the second connection pillar 2321 and the second connection layer 2322, and this SD device may be connected with at least one first gate layer 211 through the first connection pillar 2311 and the first connection layer 2312. It may be understood that the gate layers in different stack structures may share one first connection structure 230 and may share one SD device, which is favorable to increase the storage density of the memory device 10.

In some examples, as shown in FIG. 9, the first connection sub-portion 231 and the second connection sub-portion 232 have an integral structure. Composition materials of the first connection sub-portion 231 and the second connection sub-portion 232 may be the same. It may be understood that the first connection sub-portion 231 and the second connection sub-portion 232 may be fabricated in one process step. With the above arrangement, the first connection sub-portion 231 and the second connection sub-portion 232 have an integral structure, which is favorable to the electrical connection between the first connection sub-portion 231 and the second connection sub-portion 232, and improvement of the stability of the memory device 10.

In some examples, as shown in FIG. 9, in the second direction Y, a size of an end of the first connection pillar 2311 close to the second connection pillar 2321 is greater than a size of an end of the second connection pillar 2321 close to the first connection pillar 2311. In an example, on an X-Y plane, the cross section shape of the first connection pillar 2311 may be rectangular, and the cross section shape of the second connection pillar 2321 may be also rectangular. In the second direction Y, the width of the first connection pillar 2311 is greater than the width of the second connection pillar 2321. Alternatively, on the X-Y plane, the cross section shape of the first connection pillar 2311 may be an inverted trapezoid that is wide at the upper part and narrow at the lower part, and the cross section shape of the second connection pillar 2321 may be also an inverted trapezoid that is wide at the upper part and narrow at the lower part. On the X-Y plane, a size of an upper base of the first connection pillar 2311 is greater than a size of a bottom base of the second connection pillar 2321.

In this example, on a plane where the first connection pillar 2311 is in contact with the second connection pillar 2321, in the second direction Y, the width of the first connection pillar 2311 is greater than the width of the second connection pillar 2321. In addition, on the plane where the first connection pillar 2311 is in contact with the second connection pillar 2321, in the second direction Y, the first connection pillar 2311 and the second connection pillar 2321 may completely overlap, that is, edges of two sides of the second connection pillar 2321 may be located within edges of two sides of the first connection pillar 2311; or the first connection pillar 2311 and the second connection pillar 2321 may partially overlap, that is, the edge of one side of the second connection pillar 2321 is located outside the edge of one side of the first connection pillar 2311.

The above arrangement is favorable to increase a process window for achieving contact connection between the second connection pillar 2321 and the first connection pillar 2311, so as to facilitate the connection between the second connection pillar 2321 and the first connection pillar 2311, improve the connection stability between the first connection pillar 2311 and the second connection pillar 2321, and further improve the storage stability of the memory device 10.

In some examples, as shown in FIG. 9, in the second direction Y, the size of the end of the first connection pillar 2311 close to the second connection pillar 2321 is greater than the size of the end of the first connection pillar 2311 away from the second connection pillar 2321. For example, as shown in FIG. 9, on the Y-Z plane, the cross section shape of the first connection pillar 2311 may be an inverted trapezoid that is wide at the upper part and narrow at the lower part, and in the second direction Y, a width of an upper base of the cross-section of the first connection pillar 2311 is greater than a width of a lower base of the cross-section of the first connection pillar 2311.

In addition, in the second direction Y, a size of an end of the second connection pillar 2321 away from the first connection pillar 2311 is greater than a size of an end of the second connection pillar 2321 close to the first connection pillar 2311. For example, as shown in FIG. 9, on the Y-Z plane, the cross section shape of the second connection pillar 2321 may be an inverted trapezoid that is wide at the upper part and narrow at the lower part, and in the second direction Y, a width of an upper base of the cross-section of the second connection pillar 2321 is greater than a width of a lower base of the cross-section of the second connection pillar 2321. On the Y-Z plane, the lower base of the cross-section of the second connection pillar 2321 is in contact with the upper base of the cross-section of the first connection pillar 2311, such that the first connection pillar 2311 is connected with the second connection pillar 2321.

The above arrangement is favorable to increase a process window for achieving contact connection between the second connection pillar 2321 and the first connection pillar 2311, so as to facilitate the connection between the second connection pillar 2321 and the first connection pillar 2311, improve the connection stability between the first connection pillar 2311 and the second connection pillar 2321, and further improve the storage stability of the memory device 10.

In some examples, as shown in FIG. 9, the first connection structure 230 further comprises a first isolation layer 233 and a second isolation layer 234. The first isolation layer 233 is located on a side of the first connection layer 2312 close to the second connection layer 2322, and is disposed around the first connection pillar 2311. For example, the first isolation layer 233 may cover a peripheral surface of the first connection pillar 2311 to isolate the first connection pillar 2311 and avoid leakage current between the first connection pillar 2311 and other conductive structures, which is favorable to increase the storage stability of the memory device 10.

Moreover, the second isolation layer 234 is located on a side of the second connection layer 2322 facing away from the first connection layer 2312, and is disposed around the second connection pillar 2321. For example, the second isolation layer 234 may cover a peripheral surface of the second connection pillar 2321 to isolate the second connection pillar 2321 and avoid leakage current between the second connection pillar 2321 and other conductive structures, which is favorable to increase the storage stability of the memory device 10.

In some examples, as shown in FIG. 9, the size of the end of the first isolation layer 233 away from the first connection layer 2312 in the second direction is greater than the size of the end of the first isolation layer 233 close to the first connection layer 2312 in the second direction. In the second direction Y, the first isolation layer 233 has a thickness, and a thickness of an end of the first isolation layer 233 close to the second connection pillar 2321 may be greater than a thickness of an end of the first isolation layer 233 close to the first connection layer 2312. As such, an isolation effect on the end of the first connection pillar 2311 close to the second connection pillar 2321 may be further improved.

With continued reference to FIG. 9, in the second direction Y, the second isolation layer 234 has a thickness, and a thickness of an end of the second isolation layer 234 close to the first connection pillar 2311 may be greater than a thickness of an end of the second isolation layer 234 close to the first connection pillar 2311. As such, an isolation effect of the second isolation layer 234 on the end of the second connection pillar 2321 away from the first connection pillar 2311 may be further improved.

In some examples, as shown in FIG. 9, the first connection structure 230 further comprises a third isolation layer 235 and a fourth isolation layer 236.

The third isolation layer 235 is located on a side of the first connection layer 2312 facing away from the first isolation layer 233, is in contact with the first connection pillar 2311 and is disposed around the first connection pillar 2311. It may be understood that, the first isolation layer 233 is located above the first connection layer 2312 and is disposed around the first connection pillar 2311 to isolate the first connection pillar 2311 above the first connection layer 2312; and the third isolation layer 235 is located below the first connection layer 2312 and is disposed around the first connection pillar 2311 to isolate the first connection pillar 2311 below the first connection layer 2312. Both the first isolation layer 233 and the third isolation layer 235 are in contact with the first connection pillar 2311.

The fourth isolation layer 236 is located on a side of the second connection layer 2322 facing away from the second isolation layer 234, is in contact with the second connection pillar 2321 and is disposed around the second connection pillar 2321. It may be understood that, the second isolation layer 234 is located above the second connection layer 2322 and is disposed around the second connection pillar 2321 to isolate the second connection pillar 2321 above the second connection layer 2322; and the fourth isolation layer 236 is located below the second connection layer 2322 and is disposed around the second connection pillar 2321 to isolate the second connection pillar 2321 below the second connection layer 2322. Both the second isolation layer 234 and the fourth isolation layer 236 are in contact with the second connection pillar 2321.

Providing the third isolation layer 235 is favorable to isolate the first connection pillar 2311 and avoid leakage current between the first connection pillar 2311 and other conductive structures, which is favorable to improve the storage stability of the memory device 10. Providing the fourth isolation layer 236 is favorable to isolate the second connection pillar 2321 and avoid leakage current between the second connection pillar 2321 and other conductive structures, which is favorable to improve the storage stability of the memory device 10.

In some examples, as shown in FIG. 9, the first connection layer 2312 comprises a first sub-layer 3121 and a second sub-layer 3122 stacked along the first direction X. The first sub-layer 3121 is located between the first isolation layer 233 and the second sub-layer 3122, and the first isolation layer 233 is disposed around the first sub-layer 3121. Both the first sub-layer 3121 and the second sub-layer 3122 are disposed around the first connection pillar 2311, and are in contact with the first connection pillar 2311. The first sub-layer 3121 and the second sub-layer 3122 are stacked along the first direction X and are in contact with each other, such that the first sub-layer 3121 is connected with the first connection pillar 2311, the second sub-layer 3122 is connected with the first connection pillar 2311, and the first sub-layer 3121 is connected with the second sub-layer 3122. The first connection layer 2312 is connected with the first connection pillar 2311 through the first sub-layer 3121 and the second sub-layer 3122, which is favorable to improve the stability of electrical connection between the first connection layer 2312 and the first connection pillar 2311.

In an example, in the first direction X, the size of the first sub-layer 3121 may be greater than the size of the second sub-layer 3122. As such, the contact area between the first sub-layer 3121 and the first connection pillar 2311 may be increased, which is favorable to further improve the stability of the electrical connection between the first connection layer 2312 and the first connection pillar 2311.

In addition, the first isolation layer 233 may be disposed around the first sub-layer 3121, which avoids leakage current between the first sub-layer 3121 and other conductive structures, and is favorable to improve the storage stability of the memory device 10.

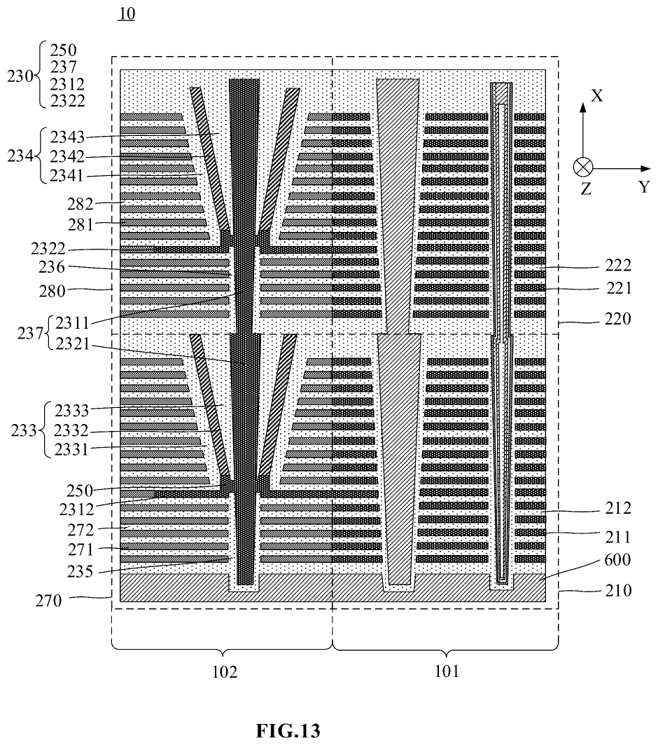

In some examples, as shown in FIG. 13, the memory device 10 further comprises a third connection layer 250. The third connection layer 250 is disposed around the connection pillar, and is connected with the first connection pillar 2311. In the first direction X, an edge of a side of the third connection layer 250 facing away from the first isolation layer 233 is connected with the first connection layer 2312. The first connection layer 2312 is disposed around the third connection layer 250, and is connected with the first gate layer 211.

With reference to FIG. 13, the first connection layer 2312 may have, for example, a ring structure; part of an outer edge of the first connection layer 2312 may be connected with the first gate layer 211, and an inner edge of the first connection layer 2312 may be connected with the third connection layer 250. The third connection layer 250 may be disposed around the first connection pillar 2311 and be in contact with the first connection pillar 2311 to achieve electrical connection. With the above arrangement, the first connection layer 2312 may be connected with the first connection pillar 2311 through the third connection layer 250 to achieve signal transmission.

In some examples, as shown in FIG. 13, the first isolation layer 233 comprises a first isolation sub-layer 2331, a second isolation sub-layer 2332 and a third isolation sub-layer 2333. The first isolation sub-layer 2331 is disposed around the connection pillar. The second isolation sub-layer 2332 is located between the first isolation sub-layer 2331 and the connection pillar, and is disposed around the connection pillar. The third isolation sub-layer 2333 is located between the second isolation sub-layer 2332 and the connection pillar, and is disposed around the connection pillar.

In an example, composition materials of the first isolation sub-layer 2331, the second isolation sub-layer 2332 and the third isolation sub-layer 2333 may include an insulation material. The insulation material includes, for example, one or a combination of silicon oxide, silicon nitride, and a high dielectric constant insulation material, and may also include other insulation materials. The composition materials of the first isolation sub-layer 2331, the second isolation sub-layer 2332 and the third isolation sub-layer 2333 may be the same or different, on which the present disclosure has no limitation.

With the above arrangement, the first isolation sub-layer 2331, the second isolation sub-layer 2332 and the third isolation sub-layer 2333 jointly isolate the first connection pillar 2311 on the side of the first connection layer 2312 close to the second connection layer 2332, which is favorable to enhance an isolation effect of the first isolation layer 233 on the first connection pillar 2311, avoid leakage current between the first sub-layer 3121 and other conductive structures, and increase the storage stability of the memory device 10.

In some examples, as shown in FIG. 13, an edge of a side of the third connection layer 250 close to the second isolation sub-layer 2332 extends towards a direction closer to the second isolation sub-layer 2332. That is, the edge of the side of the third connection layer 250 close to the second isolation sub-layer 2332 may extends upwards to be between the first isolation sub-layer 2331 and the third isolation sub-layer 2333, such that a connection strength between the third connection layer 250 and the first isolation layer 233 is increased, which is favorable to improve the structural stability of the memory device 10.

In this example, the first isolation sub-layer 2331 may be disposed around the third connection layer 250, which avoids leakage current between the third connection layer 250 and other conductive structures, and is favorable to improve the storage stability of the memory device 10.

In some examples, as shown in FIG. 10, the memory device 10 further comprises a first select gate 261, a second select gate 262, a third select gate 263 and a fourth select gate 264. The first select gate 261 is located on a side of the first stack structure 210 away from the second stack structure 220. The second select gate 262 is located on a side of the first stack structure 210 close to the second stack structure 220. The third select gate 263 is located on a side of the second stack structure 220 close to the first stack structure 210. The bit line BL connects the second select gate 262 and the third select gate 263. The fourth select gate 264 is located on a side of the second stack structure 220 away from the first stack structure 210.

With reference to FIG. 10, the bit line BL is located between the second select gate 262 and the third select gate 263, and connects the second select gate 262 and the third select gate 263. With the above arrangement, when the bit line BL is turned on, the first select gate 261 and the second select gate 262 may be turned on. Further, the bit line BL may drive the channel structure in the first stack structure 210 upwards, and meanwhile drive the channel structure in the second stack structure 220 downwards. The above arrangement is favorable to increase the current intensity in the channel structure and solve the problem that the current intensity in part of the channel structure away from the bit line BL is weak.

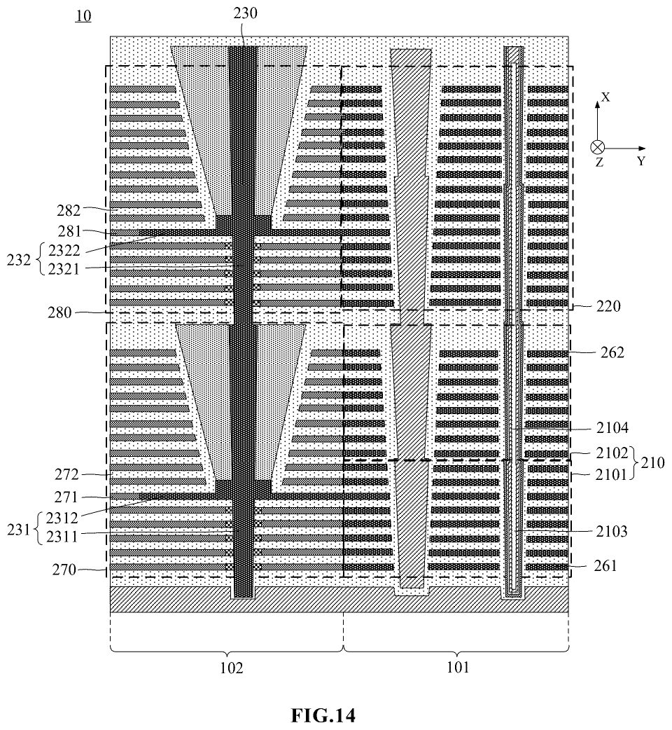

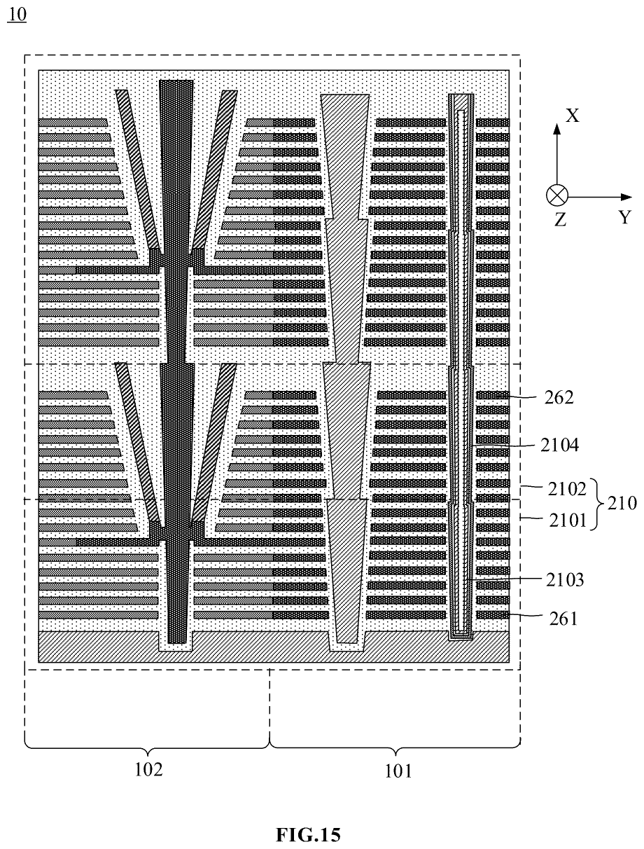

In some examples, as shown in FIGS. 14 and 15, the first stack structure 210 comprises a first stack sub-structure 2101 and a second stack sub-structure 2102 stacked along the first direction X, a first channel structure 2103, and a second channel structure 2104. The first channel structure 2103 extends through the first stack sub-structure 2101, and the second channel structure 2104 extends through the second stack sub-structure 2102. The first channel structure 2103 is located between the first select gate 261 and the second select gate 262.

In this example, as shown in FIGS. 14 and 15, the first stack structure 210 may comprise the first stack sub-structure 2101 and the second stack sub-structure 2102 stacked along the first direction X, which may be understood as that the first stack structure 210 may comprise a plurality of stack sub-structures, for example, the first stack structure 210 may include, but is not limited to, 2, 4, or 8 stack sub-structures, etc., thereby increasing the storage capacity of the memory device 10. In addition, the first stack sub-structure 2101 and the second stack sub-structure 2102 are stacked along the first direction X, which is favorable to increase the storage density of the memory device 10. In this example, the first stack structure 210 comprising 2 stack sub-structures is illustrated as an example.

With continued reference to FIGS. 14 and 15, the first channel structure 2103 extends through the first stack sub-structure 2101, and the second channel structure 2104 extends through the second stack sub-structure 2102. In an example, the first channel structure 2103 and the second channel structure 2104 may be connected to increase the storage capacity of the memory device 10. Among the plurality of first gate layers 211 around the first channel structure 2103, the first gate layer 211 farthest away from the second channel structure 2104 may be set as the first select gate 261. Among the plurality of first gate layers 211 around the second channel structure 2104, the first gate layer farthest away from the first channel structure 2103 may be set as the second select gate 262. As such, the first channel structure 2103 and the second channel structure 2104 is located between the first select gate 261 and the second select gate 262, which is favorable to read and write operations of the memory device 10 for the first channel structure 2103 and the second channel structure 2104.

In some examples, as shown in FIGS. 11 and 12, the memory device 10 comprises the first region 101 and the second region 102, and the first region 101 adjoins the second region 102. Both the first stack structure 210 and the second stack structure 220 are located in the first region 101, the first connection structure 230 is located in the second region 102, and the second region 102 is located on a side of the first region 101. For example, in FIG. 11, in the second direction Y, the second region 102 is located on a side of the first region 101, and only one side of the first region 101 adjoins only one side of the second region 102.

Alternatively, in some other examples, as shown in FIG. 12, the first region 101 comprises a first sub-region 1011 and a second sub-region 1012, and the second region 102 is located between the first sub-region 1011 and the second sub-region 1012.

With the above arrangement, the first connection structure 230 in the second region 102 may be connected with one first gate layer 211, and the first connection structure 230 is connected with one second gate layer 221. Compared with that the gate line contacts G-CNT in a staircase arrangement lead out the first gate layer 211 and the second gate layer 221 one by one in FIG. 4, in this example, one first gate layer 211 and the first one of the second gate layers 221 share one first connection structure 230, which is favorable to control the area of the second region 102 and increase the storage density of the memory device 10.

In some examples, as shown in FIG. 13, the memory device 10 further comprises a third stack structure 270 and a fourth stack structure 280 that are stacked along the first direction X. Both the third stack structure 270 and the fourth stack structure 280 are located in the second region 102. A thick dielectric layer may be disposed between the third stack structure 270 and the fourth stack structure 280.

The first connection pillar 2311 extends through the third stack structure 270, and the third stack structure 270 comprises a plurality of third dielectric layers 271 and a plurality of fourth dielectric layers 272 stacked alternately along the first direction X, and at least one third dielectric layer 271 is connected with at least one first connection layer 2312. Here, the first connection layer 2312 connected with the third dielectric layer 271 may be connected with one first gate layer 211.

The second connection pillar 2321 extends through the fourth stack structure 280, and the fourth stack structure 280 comprises a plurality of fifth dielectric layers 281 and a plurality of sixth dielectric layers 282 stacked alternately along the first direction X, and at least one fifth dielectric layer 281 is connected with at least one second connection layer 2322. Here, the second connection layer 2322 connected with the fifth dielectric layer 281 may be connected with one second gate layer 221.

In an example, the third dielectric layer 271 may be connected with the first gate layer 211, and the fourth dielectric layer 272 may be connected with the first dielectric layer 212. In addition, composition materials of the fourth dielectric layer 272 and the first dielectric layer 212 may be the same, and furthermore, the fourth dielectric layer 272 may be disposed in the same layer as the first dielectric layer 212. Disposed in the same layer means that a plurality of patterns are on the same pattern layer. The patter layer refers to a film layer formed by a single patterning process, which refers to a process that can form at least one pattern with a certain shape. For example, a thin film is formed on a substrate by any one of multiple film formation processes such as deposition, spraying, sputtering, etc., and is then patterned to form a film layer containing at least one pattern, which is referred to as the pattern layer. Patterning steps include photoresist coating, exposure, development, etching, and photoresist stripping, etc. In this example, a relationship of positions of the plurality of patterns belonging to the same pattern layer is referred to as being disposed in the same layer.

In an example, the fifth dielectric layer 281 may be connected with the second gate layer 221, and the sixth dielectric layer 282 may be connected with the second dielectric layer 222. In addition, composition materials of the sixth dielectric layer 282 and the second dielectric layer 222 may be the same, and furthermore, the sixth dielectric layer 282 may be disposed in the same layer as the second dielectric layer 222.

In this example, the composition materials of the first dielectric layer 212, the second dielectric layer 222, the fourth dielectric layer 272 and the sixth dielectric layer 282 are all oxides, and the composition materials of the third dielectric layer 271 and the fifth dielectric layer 281 are both nitrides.

In some examples, with reference to FIGS. 8, 10 and 11, the memory device 10 further comprises a second connection structure 240. The second connection structure 240 is located on a side of the first stack structure 210 and the second stack structure 220 along the second direction. For example, in FIG. 11, both the first stack structure 210 and the second stack structure 220 may be located in the second region 102, and the second connection structure 240 may be located in the first region 101. One of the first select gate 261 and the second select gate 262 is connected with the second connection structure 240. That is, the second connection structure 240 is connected with the first select gate 261, or the second connection structure 240 is connected with the second select gate 262.

In some other examples, with reference to FIGS. 8 and 10, one of the third select gate 263 and the fourth select gate 264 is connected with the second connection structure 240. That is, the second connection structure 240 is connected with the third select gate 263, or the second connection structure 240 is connected with the fourth select gate 264.

With the above arrangement, the memory device 10 may selectively turn on the channel structure in the first stack structure 210 or the channel structure in the second stack structure 220 through the second connection structure 240, and then further selectively read or write a storage node in the first stack structure 210 or the second stack structure 220 through the first connection structure 230 and the bit line BL.

In an example, there may be a plurality of second connection structures 240, for example, one second connection structure 240 connected with the first select gate 261, one second connection structure 240 connected with the second select gate 262, one second connection structure 240 connected with the third select gate 263 and one second connection structure 240 connected with the fourth select gate 264. As such, by disposing the plurality of second connection structures 240, when one second connection structure 240 is in poor connection, the first stack structure 210 and the second stack structure 220 may be selected through other second connection structures 240, which is favorable to improve the storage stability of the memory device 10.

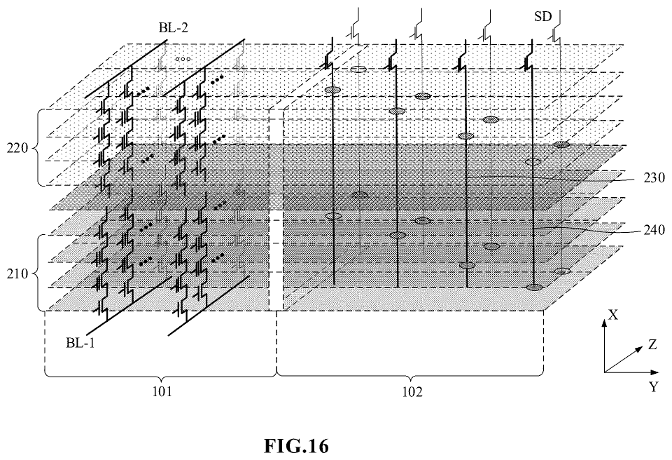

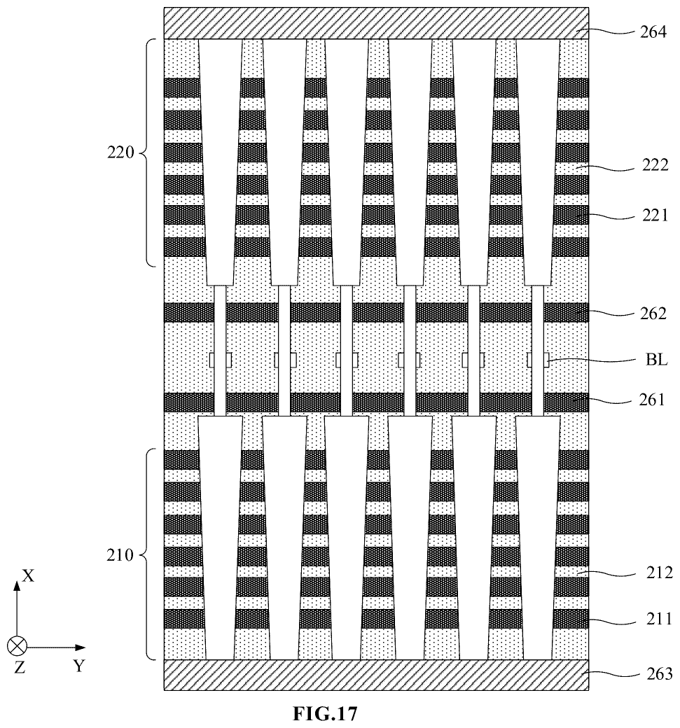

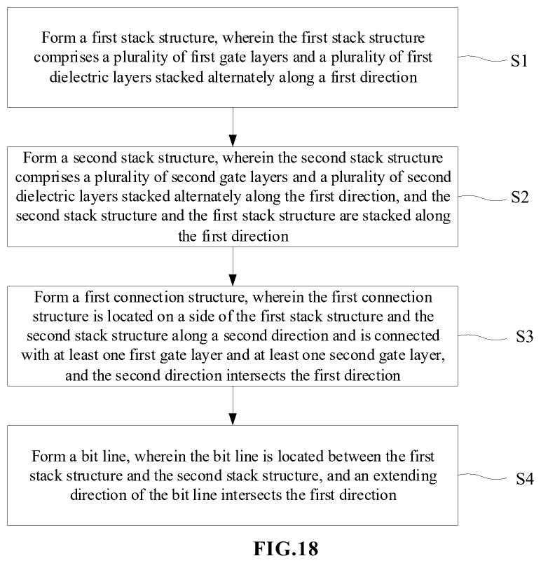

Some examples of the present disclosure further provide a memory device 10. With reference to FIGS. 13 and 16, the memory device 10 comprises a first stack structure 210, a second stack structure 220 and a first connection structure 230. The first stack structure 210 comprises a plurality of first gate layers 211 and a plurality of first dielectric layers 212 stacked alternately along a first direction X. The second stack structure 220 comprises a plurality of second gate layers 221 and a plurality of second dielectric layers 222 stacked alternately along the first direction X. The second stack structure 220 and the first stack structure 210 are stacked along the first direction X.

The first stack structure 210 may be disposed on a semiconductor layer 600. In an example, the first stack structure 210 may be in direct contact with the semiconductor layer 600. In an example, a composition material of the semiconductor layer 600 may include, for example, monocrystalline silicon, monocrystalline germanium, a group III-V compound semiconductor material, a group II-VI compound, and other suitable semiconductor materials.

It is to be noted that, the first stack structure 210 and the second stack structure 220 in this example may be referred to the illustration of the first stack structure 210 and the second stack structure 220 in some examples above, which is no longer repeated herein.

As shown in FIG. 13, the first connection structure 230 comprises a connection pillar 237, at least one first connection layer 2312 and at least one second connection layer 2322. The connection pillar 237 is located on a side of the first stack structure 210 and the second stack structure 220 along a second direction Y. The first connection layer 2312 is parallel to the second direction Y, and one first connection layer 2312 is connected with one first gate layer 211 and the connection pillar 237. The second connection layer 2322 is parallel to the second direction Y, and one second connection layer 2322 is connected with one second gate layer 221 and the connection pillar 237.

It is to be noted that a composition material of the first connection structure 230 may be referred to the illustration of the first connection structure 230 in some examples above.

In this example, the first connection structure 230 may comprise one first connection layer 2312 or a plurality of first connection layer 2312, and the first connection structure 230 may comprise one second connection layer 2322 or a plurality of second connection layers 2322. The first connection structure 230 comprising one first connection layer 2312 and one second connection layer 2322 is illustrated as an example below.

With the above arrangement, the first connection layer 2312 in the first connection structure 230 is connected with the first gate layer 211 in the first stack structure 210, the second connection layer 2322 in the first connection structure 230 is connected with the second gate layer 221 in the second stack structure 220, and the connection pillar is connected with an SD device. For comparison, in FIG. 4, one first gate layer 211 is connected with the SD device through one gate line contact G-CNT, one second gate layer 221 is connected with the SD device through one gate line contact G-CNT, and the plurality of gate line contacts G-CNT are in a staircase arrangement, resulting in a large footprint of the plurality of gate line contacts G-CNT. The number of the first connection structures 230 in this example is less than the number of the gate line contacts G-CNT, and the number of the SD devices in this example is also smaller, such that the footprint of the first connection structure 230 is smaller than the footprint of the gate line contact G-CNT, and meanwhile, the footprint of the SD device is also reduced, which is favorable to increase the storage density of the memory device 10.

When the memory device 10 comprises more stack structures, for example, the memory device 10 may comprise 4, 6, or 8 stack structures, or the like, at this point, the first connection structure 230 may be connected with one gate layer in each of the plurality of stack structures. With the above arrangement, even if more stack structures are added, the number of the first connection structures 230 will not be increased, i.e., the footprint of the first connection structure 230 will not be increased, which is favorable to increase the storage density of the memory device 10 and to the development of the memory device 10 towards a large capacity and a small size.

In addition, it has been mentioned above that, the number of the stack structures is increasing and the number of the SD devices is also increasing in order to increase the capacity of the memory device 10 in the art. In order to control the size of the memory device 10, the problem of reducing the size of the SD device need to be addressed. The first connection structure 230 being connected with one gate layer in each of the plurality of stack structures in this example will not increase the number of the SD devices, and thus, the demand on reducing the size of the SD device may be reduced.

In some examples, as shown in FIGS. 10 and 16, the memory device 10 further comprises a first select gate 261, a second select gate 262, a third select gate 263, a fourth select gate 264 and a second connection structure 240. The first select gate 261 is located on a side of the first stack structure 210 away from the second stack structure 220, the second select gate 262 is located on a side of the first stack structure 210 close to the second stack structure 220, the third select gate 263 is located on a side of the second stack structure 220 close to the first stack structure 210, and the fourth select gate 264 is located on a side of the second stack structure 220 away from the first stack structure 210.

The second connection structure 240 is located on a side of the first stack structure 210 and the second stack structure 220 along the second direction Y, and the second connection structure 240 and the first connection structure 230 may be located on the same side of the first stack structure 210 and the second stack structure 220. One of the first select gate 261, the second select gate 262, the third select gate 263 and the fourth select gate 264 is connected with the second connection structure 240.

With the above arrangement, the memory device 10 may selectively turn on the channel structure in the first stack structure 210 or the channel structure in the second stack structure 220 through the second connection structure 240, and then further selectively read or write a storage node in the first stack structure 210 or the second stack structure 220 through the first connection structure 230 and the bit line BL.

In some examples, as shown in FIG. 16, the memory device 10 further comprises a first bit line BL-1 and a second bit line BL-2. The first bit line BL-1 is located on a side of the first select gate 261 away from the first stack structure 210, and the second bit line BL-2 is located on a side of the fourth select gate 264 away from the first stack structure 210. An extending direction of the first bit line BL-1 and the second bit line BL-2 intersects the first direction X. The extending directions of the first bit line BL-1 and the second bit line BL-2 may be parallel with each other.

It is to be noted that when the plurality of stack structures continue to be stacked in the memory device 10, the first bit line BL-1 and the second bit line BL-2 may be located on two sides of all the stack structures along the first direction X, and an active layer is disposed between adjacent ones of the stack structures.

In this example, the active layer may be formed (e.g., a silicon material is deposited) between the first stack structure 210 and the second stack structure 220, the first dielectric layer 212 in the first stack structure 210 is in contact with a side of the active layer, and the second dielectric layer 222 in the second stack structure 220 is in contact with the other side of the active layer. A channel structure in the first stack structure 210 may extend through the first stack structure 210 and part of the active layer, a channel structure in the second stack structure 220 may extend through the second stack structure 220 and part of the active layer. The channel structure in the first stack structure 210 and the channel structure in the second stack structure 220 are connected.

With the above arrangement, the first bit line BL-1, the channel structure in the first stack structure 210, the channel structure in the second stack structure 220 and the second bit line BL-2 are all connected with each other, such that the channel structures in the first stack structure 210 and the second stack structure 220 may be driven thorough the first bit line BL-1 and the second bit line BL-2. Compared with the solution that the bit line BL is located at the topmost of the plurality of stack structures, in this example, the bit line BL is located between the first stack structure 210 and the second stack structure 220, which is favorable to increase the current intensity in the channel structure and solve the problem that the current intensity in part of the channel structure away from the bit line BL is weak.

In some examples, as shown in FIG. 11, the memory device 10 comprises a first region 101 and a second region 102, wherein the first region 101 adjoins the second region 102 in the second direction Y, both the first stack structure 210 and the second stack structure 220 are located in the first region 101, and the first connection structure 230 is located in the second region 102. In an example, in the second direction Y, the second region 102 is located on a side of the first region 101, and only one side of the first region 101 adjoins only one side of the second region 102. In some examples, the second connection structure 240 is also located in the second region 102.

Alternatively, in some other examples, the first region 101 comprises a first sub-region 1011 and a second sub-region 1012, and the second region 102 is located between the first sub-region 1011 and the second sub-region 1012.

With the above arrangement, the first connection structure 230 in the second region 102 may be connected with one first gate layer 211, and the first connection structure 230 is connected with one second gate layer 221. Compared with that the gate line contacts G-CNT in a staircase arrangement lead out the first gate layer 211 and the second gate layer 221 one by one in FIG. 4, in this example, one first gate layer 211 and the first one of the second gate layers 221 share one first connection structure 230, which is favorable to control the area of the second region 102 and increase the storage density of the memory device 10.

In this example, the memory device 10 may further comprise a third stack structure 270 and a fourth stack structure 280 stacked along the first direction X, wherein both the third stack structure 270 and the fourth stack structure 280 are located in the second region 102. The connection pillar may extend through the third stack structure 270 and the fourth stack structure 280. Specific structures of the third stack structure 270 and the fourth stack structure 280 may be referred to the illustration of the third stack structure 270 and the fourth stack structure 280 in some examples above.

Some examples of the present disclosure further provide a memory device 10. As shown in FIGS. 8, 9 and 17, the memory device 10 comprises a first stack structure 210 and a second stack structure 220 stacked along a first direction, a first select gate 261, a second select gate 262 and a bit line BL. The first stack structure 210 comprises a plurality of first gate layers 211 and a plurality of first dielectric layers 212 stacked alternately along the first direction X, and the second stack structure 220 comprise a plurality of second gate layers 221 and a plurality of second dielectric layers 222 stacked alternately along the first direction X.

The memory device 10 comprises a first select gate 261 and a second select gate 262. The first select gate 261 is located on a side of the first stack structure 210 close to the second stack structure 220, and the second select gate 262 is located on a side of the second stack structure 220 close to the first stack structure 210. In an example, one of the plurality of first gate layers 211 closest to the second stack structure 220 may be set as the first select gate 261, and one of the plurality of second gate layers 221 closest to the first stack structure 210 may be set as the second select gate 262.

The bit line BL may be located between the first select gate 261 and the second select gate 262, and connected with the first select gate 261 and the second select gate 262. An extending direction of the bit line BL intersects the first direction X. In an example, the bit line BL may extend in a Y-Z plane, for example, the extending direction of the bit line BL may be parallel to the third direction Z. There may be a plurality of bit lines BL spaced apart along the second direction Y.

As shown in FIG. 17, the bit line BL is connected with a channel structure in the first stack structure 210, and is also connected with a channel structure in the second stack structure 220. With the above arrangement, the bit line BL is located between the first stack structure 210 and the second stack structure 220, and can drive the channel structure in the first stack structure 210 upwards, and meanwhile drive the channel structure in the second stack structure 220 downwards. In some other examples, when the bit line BL is located at topmost (an end of the second stack structure 220 away from the first stack structure 210) of the plurality of stack structures, due to the resistance in the channel structure, the current intensity in part of the channel structure away from the bit line BL is weak. Compared with the solution that the bit line BL is located at the topmost of the plurality of stack structures, in this example, the bit line BL is located between the first stack structure 210 and the second stack structure 220, which is favorable to increase the current intensity in the channel structure and solve the problem that the current intensity in part of the channel structure away from the bit line BL is weak.

In some examples, as shown in FIG. 9, the memory device 10 comprises a first connection structure 230. The first connection structure 230 is located on a side of the first stack structure 210 and the second stack structure 220 along the second direction Y, and is connected with at least one first gate layer 211 and at least one second gate layer 221.

In this example, the first connection structure 230 may be referred to the illustration of the first connection structure 230 in some examples above, which is no longer repeated herein.

With the above arrangement, one first gate layer 211 and one second gate layer 221 may share one first connection structure 230 and may share one SD device. Thus, when the memory device 10 has two stack structures (i.e., the first stack structure 210 and the second stack structure 220), compared with one first gate layer 211 being connected with one SD device through one gate line contact G-CNT (with reference to FIGS. 4 and 8) and one second gate layer 221 being connected with one SD device through one gate line contact G-CNT, the number of the first connection structures 230 in this example is less than the number of the gate line contacts G-CNT, and the number of the SD devices in this example is also smaller, such that the footprint of the first connection structure 230 is smaller than the footprint of the gate line contact G-CNT, and meanwhile, the footprint of the SD device is also reduced, which is favorable to increase the storage density of the memory device 10.

When the memory device 10 comprises more stack structures, for example, the memory device 10 may comprise 4, 6, or 8 stack structures, or the like, at this point, the first connection structure 230 may be connected with one gate layer in each of the plurality of stack structures. With the above arrangement, even if more stack structures are added, the number of the first connection structures 230 will not be increased, i.e., the footprint of the first connection structure 230 will not be increased, which is favorable to increase the storage density of the memory device 10 and to the development of the memory device 10 towards a large capacity and a small size.

In addition, it has been mentioned above that, the number of the stack structures is increasing and the number of the SD devices is also increasing in order to increase the capacity of the memory device 10 in the art. In order to control the size of the memory device 10, the problem of reducing the size of the SD device need to be addressed. The first connection structure 230 being connected with one gate layer in each of the plurality of stack structures in this example will not increase the number of the SD devices, and thus, the demand on reducing the size of the SD device may be reduced.

In some examples, as shown in FIGS. 16 and 17, the memory device 10 further comprises a third select gate 263, a fourth select gate 264 and a second connection structure 240. The third select gate 263 is located on a side of the first stack structure 210 away from the second stack structure 220, and the fourth select gate 264 is located on a side of the second stack structure 220 away from the first stack structure 210. In an example, one of the plurality of first gate layers 211 farthest away from the second stack structure 220 may be set as the third select gate 263. One of the plurality of second gate layers 221 farthest away from the first stack structure 210 may be set as the fourth select gate 264.

The second connection structure 240 is located on a side of the first stack structure 210 and the second stack structure 220 along the second direction Y. The second connection structure 240 and the first connection structure 230 may be located on the same side of the first stack structure 210 and the second stack structure 220. One of the first select gate 261, the second select gate 262, the third select gate 263 and the fourth select gate 264 is connected with the second connection structure 240.

With the above arrangement, the memory device 10 may selectively turn on the channel structure in the first stack structure 210 or the channel structure in the second stack structure 220 through the second connection structure 240, and then further selectively read or write a storage node in the first stack structure 210 or the second stack structure 220 through the first connection structure 230 and the bit line BL.

In an example, there may be a plurality of second connection structures 240, for example, one second connection structure 240 connected with the first select gate 261, one second connection structure 240 connected with the second select gate 262, one second connection structure 240 connected with the third select gate 263 and one second connection structure 240 connected with the fourth select gate 264. As such, by disposing the plurality of second connection structures 240, when one second connection structure 240 is in poor connection, the first stack structure 210 and the second stack structure 220 may be selected through other second connection structures 240, which is favorable to improve the storage stability of the memory device 10.

Some examples of the present disclosure provide a fabrication method of a memory device, which is illustrated below in conjunction with FIGS. 18-43.

FIG. 18 is a flow diagram of a fabrication method of a memory device according to some examples. As shown in FIG. 18, the fabrication method of the memory device provided by some examples of the present disclosure comprises: S1-S4.

At S1, a first stack structure is formed, wherein the first stack structure comprises a plurality of first gate layers and a plurality of first dielectric layers stacked alternately along a first direction.

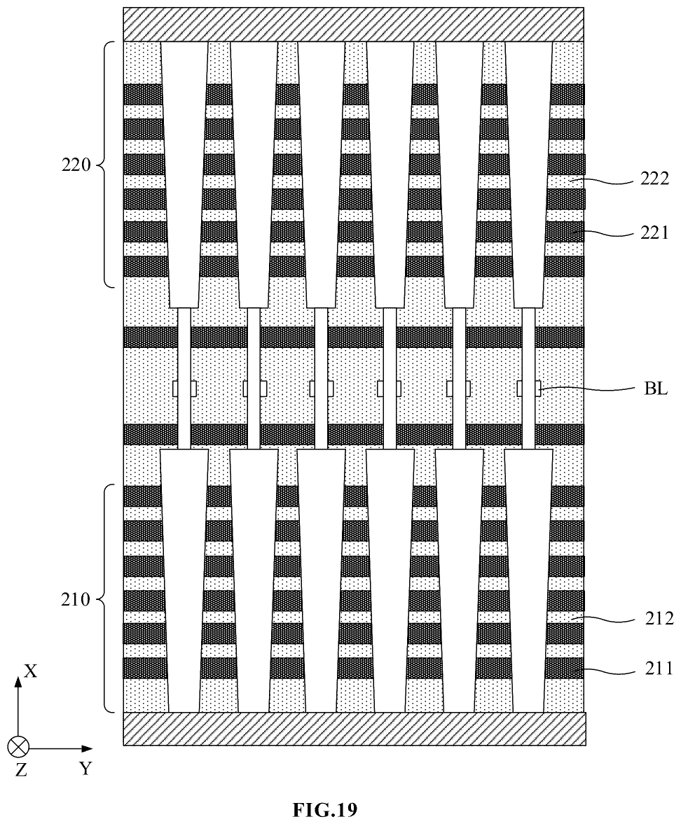

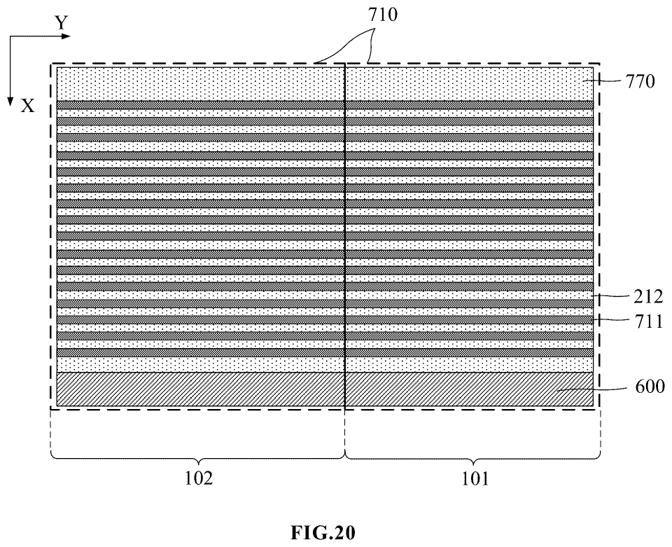

In this operation, with reference to FIGS. 19 and 20, a semiconductor layer 600 is provided, and the first stack structure 210 is formed on the semiconductor layer 600. For example, the first dielectric layers 212 and the first gate layers 211 may be alternately formed on the semiconductor layer 600 through a deposition process, including, but not limited to, one or more of physical vapor deposition (PVD), chemical vapor deposition (CVD), and atomic layer deposition (ALD).

The semiconductor layer 600 may comprise silicon (e.g., monocrystalline silicon), silicon germanium (SiGe), gallium arsenide (GaAs), germanium (Ge), silicon on insulator (SOI) and/or any other suitable semiconductor materials. In some examples, the semiconductor layer 600 comprises silicon, for example, monocrystalline silicon and polysilicon.

The first stack structure 210 comprises the plurality of first gate layers 211 and the plurality of first dielectric layers 212 stacked alternately along the first direction X. For example, first gate layers 211 and first dielectric layers 212 disposed alternately along the first direction X are stacked to form the plurality of first gate layers 211 and the plurality of first dielectric layers 212 spaced apart from each other. It may also be understood that, one first gate layer 211 and one first dielectric layer 212 jointly constitute one first gate structure pair, and the first stack structure 210 comprises a plurality of first gate structure pairs stacked along the first direction X.

In an example, the number of the first gate layers 211 and the first dielectric layers 212 may be 4, 16, 32, 64, 128, 256, or the like. The thickness (i.e., the size along the first direction X) of the first gate layer 211 is approximately equal to or different from the thickness of the first dielectric layer 212. For example, the thickness of the first dielectric layer 212 is greater than the thickness of the first gate layer 211.

In an example, the first gate layer 211 may comprise a conductive material that includes, but is not limited to, one or a combination of tungsten (W), cobalt (Co), copper (Cu), aluminum (Al), polysilicon, doped silicon, and silicides, or may be other suitable conductive materials. In some examples, the first gate layer 211 comprises a metal layer, e.g., a tungsten layer. In some examples, the first gate layer 211 comprises a doped polysilicon layer. The polysilicon may be doped to a desired doping concentration using a suitable dopant, such that the polysilicon may become a conductive material used for the first gate layer 211.

In an example, the first dielectric layer 212 may comprise an insulation material that may include one or a combination of silicon oxide, silicon nitride, silicon oxynitride and a high dielectric constant insulation material, or may be other suitable insulation materials. A dielectric constant of silicon oxynitride is higher than a dielectric constant of silicon oxide. For example, in an environment at about 20° C., the dielectric constant of silicon oxynitride is 4-7, for example, 3.8, 4, 4.8, 5.3, 5.9, 6, 6.36, 6.88, 7, 7.2, etc. In some examples, the first dielectric layer 212 comprises a silicon oxide layer. In some examples, the first dielectric layer 212 comprises a silicon oxynitride layer.

In an example, the thickness (i.e., the size along the first direction X) of the first gate layer 211 may be between 10 nm and 50 nm, for example, 10 nm, 15 nm, 18.3 nm, 20 nm, 25 nm, 27.7 nm, 30 nm, 35 nm, 40 nm, 45 nm, 50 nm, etc. Similarly, the thickness (i.e., the size along the first direction X) of the first dielectric layer 212 may be between 10 nm and 50 nm, for example, 10 nm, 15 nm, 18.3 nm, 20 nm, 25 nm, 27.7 nm, 30 nm, 35 nm, 40 nm, 45 nm, 50 nm, etc. The first gate layer 211 may surround a gate line G surrounding the memory cell string (with reference to FIG. 6), and may extend laterally (i.e., along the second direction Y) as a word line WL (with reference to FIG. 4).

At S2, a second stack structure is formed, wherein the second stack structure comprises a plurality of second gate layers and a plurality of second dielectric layers stacked alternately along the first direction, and the second stack structure and the first stack structure are stacked along the first direction.

In this operation, with reference to FIGS. 19, 20 and 21, before forming the second stack structure 220, an isolation dielectric layer 770 may be deposited on the first stack structure 210 using a deposition process. In an example, a material of the isolation dielectric layer 770 may be the same as that of the first dielectric layer 212. The topmost first dielectric layer 212 of the first stack structure 210 and the isolation dielectric layer 770 may be formed in the same process step.

After forming the isolation dielectric layer 770, the second dielectric layers 222 and the second gate layers 221 may continue to be alternately formed on the isolation dielectric layer 770 through a deposition process. The composition material, thickness and number of the second gate layers 221 and the second dielectric layers 222 may be referred to the above examples of the composition material, thickness and number of the first gate layers 211 and the first dielectric layers 212. The composition material, thickness and number of the second gate layers 221 may be the same as or different from those of the first gate layers 211, and the composition material, thickness and number of the second dielectric layer 222 may be the same as or different from those of the first dielectric layers 212.

At S3, a first connection structure is formed, wherein the first connection structure is located on a side of the first stack structure and the second stack structure along a second direction and is connected with at least one first gate layer and at least one second gate layer, and the second direction intersects the first direction.

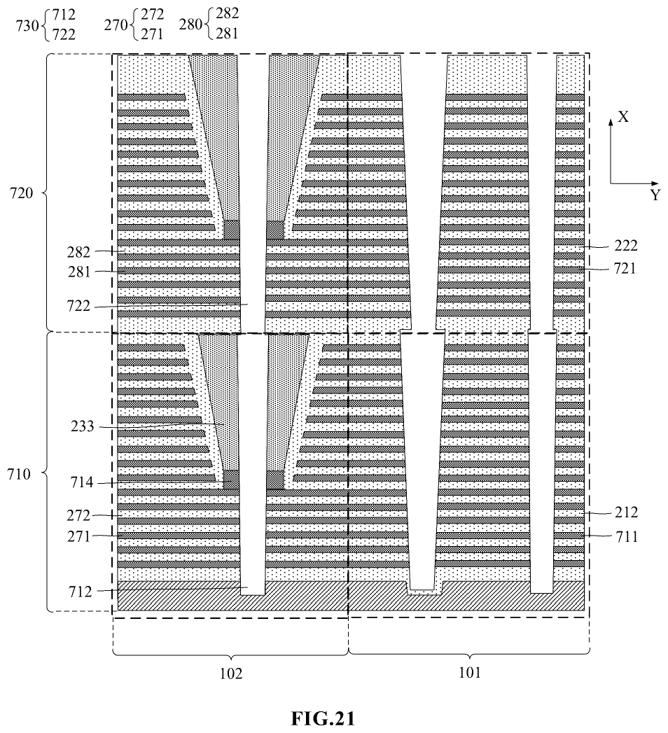

In this operation, with reference to FIG. 21, before forming the first connection structure 230, a third stack structure 270 and a fourth stack structure 280 stacked together may be formed on a side of the first stack structure 210 and the second stack structure 220 along the second direction Y. The first connection structure 230 is formed through an etching process, a deposition process, etc. Moreover, the first connection structure 230 is connected with at least one first gate layer 211 and at least one second gate layer 221.

In an example, a composition material of the first connection structure 230 may include a conductive material that includes, but is not limited to, one or a combination of tungsten (W), cobalt (Co), copper (Cu), aluminum (Al), polysilicon, doped silicon, and silicides, or may be also other suitable conductive materials.

After forming the first connection structure 230, an SD device may be also formed, and is connected with the first connection structure 230.

According to the memory device 10 fabricated by the above operations, one SD device may be connected with at least one first gate layer 211 and at least one second gate layer 221 through the first connection structure 230. One first gate layer 211 and one second gate layer 221 may share one first connection structure 230 and may share one SD device. Thus, when the memory device 10 has two stack structures (i.e., the first stack structure 210 and the second stack structure 220), compared with one first gate layer 211 being connected with one SD device through one gate line contact G-CNT and one second gate layer 221 being connected with one SD device through one gate line contact G-CNT, the number of the first connection structures 230 in this example is less than the number of the gate line contacts G-CNT, and the number of the SD devices in this example is also smaller, such that the footprint of the first connection structure 230 is smaller than the footprint of the gate line contact G-CNT, and meanwhile, the footprint of the SD device is also reduced, which is favorable to increase the storage density of the memory device 10.

After forming the second stack structure 220 and before forming the first connection structure 230, a plurality of stack structure may continue to be formed along the first direction X, for example, 2, 4 or 6 stack structures or the like may continue to be formed. After forming the plurality of stack structures, during the formation of the first connection structure 230, the first connection structure 230 may be connected with one gate layer in each of the plurality of stack structures.

According to the memory device 10 formed by the above fabrication method, even if more stack structures are formed, the number of the first connection structures 230 will not be increased. Therefore, according to the memory device 10 obtained by the above fabrication method, the footprint of its first connection structure 230 will not increase with the increase of the stack structures, which is favorable to increase the storage density of the memory device 10 and to the development of the memory device 10 towards a large capacity and a small size.

In addition, the number of the stack structures is increasing and the number of the SD devices is also increasing in order to increase the capacity of the memory device 10 in the art. In order to control the size of the memory device 10, the problem of reducing the size of the SD device need to be addressed. The first connection structure 230 obtained by the fabrication method of this example is connected with one gate layer in each of the plurality of stack structures, which will not increase the number of the SD devices, and thus, the demand on reducing the size of the SD device may be reduced.

At S4, a bit line is formed, wherein the bit line is located between the first stack structure and the second stack structure, and an extending direction of the bit line intersects the first direction.

In this operation, as shown in FIG. 19, the extending direction of the bit line BL intersects the first direction X, for example, the bit line BL may extend along the third direction Z.

According to the memory device 10 fabricated in this operation, its bit line BL is located between the first stack structure 210 and the second stack structure 220 and is connected with a channel structure in the first stack structure 210 and a channel structure in the second stack structure 220. Therefore, the bit line BL may drive the channel structure in the first stack structure 210 upwards, and meanwhile drive the channel structure in the second stack structure 220 downwards. Compared with the bit line BL being formed on the second stack structure 220, in this example, the bit line BL is formed between the first stack structure 210 and the second stack structure 220, which is favorable to increase the current intensity in the channel structure in the first stack structure 210 and the channel structure in the second stack structure 220 and solve the problem that the current intensity in part of the channel structure away from the bit line BL is weak.

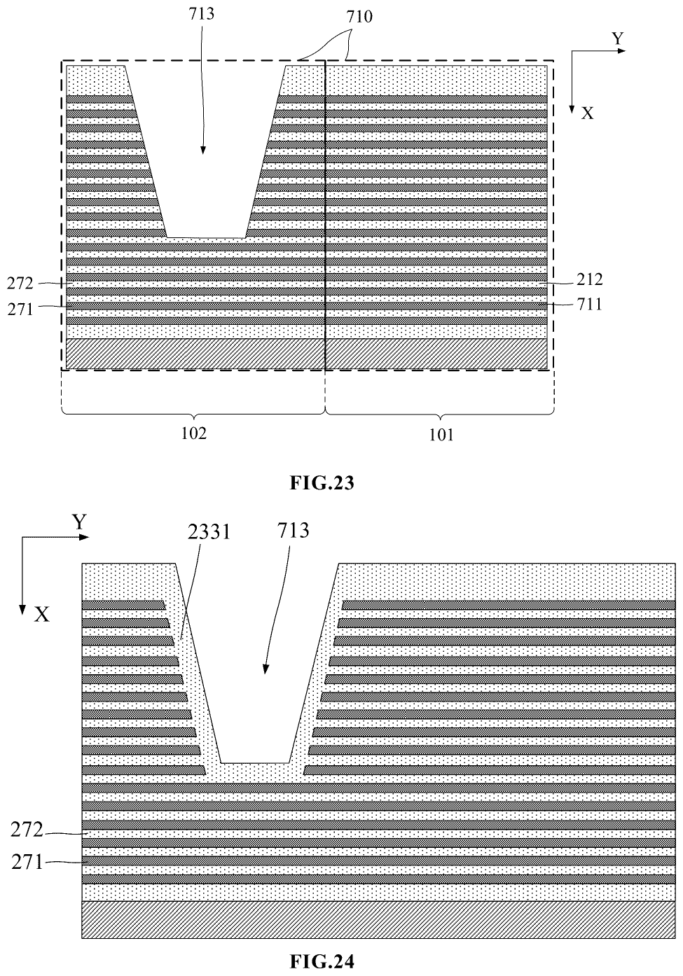

In some examples, as shown in FIG. 23, forming the first stack structure 210 comprises: forming a first deck structure 710, wherein a first region 101 of the first deck structure 710 comprises a plurality of first sacrificial layers 711 and a plurality of first dielectric layers 212 stacked alternately along the first direction and adjoins a second region 102 of the first deck structure 710, and the second region 102 of the first deck structure 710 is located on a side of the first region 101 of the first deck structure 710 along the second direction Y.

In this operation, as shown in FIG. 23, the first dielectric layers 212 and the first sacrificial layers 711 may be formed alternately using a deposition process. In an example, a material of the first dielectric layer 212 may include silicon oxide, and a material of the first sacrificial layer 711 may include silicon nitride.

As shown in FIG. 21, forming the second stack structure 220 comprises: forming a second deck structure 720 that is located on a side of the bit line BL away from the first deck structure 710, wherein a first region 101 of the second deck structure 720 comprises a plurality of second sacrificial layers 721 and a plurality of second dielectric layers 222 stacked alternately along the first direction and adjoins a second region 102 of the second deck structure 720, and the second region 102 of the second deck structure 720 is located on a side of the first region 101 of the second deck structure 720 along the second direction Y.

In this operation, as shown in FIG. 21, for example, the second dielectric layers 222 and the second sacrificial layers 721 may be formed alternately on the first deck structure 710 using a deposition process. In an example, a material of the second dielectric layer 222 may include silicon oxide, and a material of the second sacrificial layer 721 may include silicon nitride.

As shown in FIG. 21, after forming the first deck structure 710 and before forming the second deck structure 720, the fabrication method comprises: removing part of the first deck structure 710 to form a first connection hole 712, wherein the first connection hole 712 is located in the second region 102 of the first deck structure 710.

In this operation, the first connection hole 712 may extend through the first deck structure 710 into the semiconductor layer 600. The first connection hole 712 may be formed through any suitable processes. For example, a patterned photoresist layer may be formed on the first deck structure 710. The patterned photoresist layer can expose a part of the first deck structure 710 for forming the first connection hole 712. A suitable etching process may be performed to remove the part of the first deck structure 710 for forming the first connection hole 712. For example, the etching process may include a dry etching process.

After forming the first connection hole 712, the patterned photoresist layer on the first deck structure 710 may be removed, for example, a surface of the first deck structure 710 may be planarized by chemical mechanical polishing (CMP) to remove the patterned photoresist layer on the first deck structure 710.

In some examples, the operation of removing the first deck structure 710 to form the first connection hole 712 further comprises: forming a first gate slit 743 that is located in the first region 101 of the first deck structure 710.

In this operation, with continued reference to FIG. 21, a first channel hole 751 may be also formed, the first gate slit is located between the first channel hole 751 and the first connection hole 712, and both the first channel hole 751 and the first gate slit are located in the first region 101 of the first deck structure 710. The first connection hole 712, the first gate slit and the first channel hole 751 may be formed through a single process step, for example, through a dry etching process. The first connection hole 712, the first gate slit and the first channel hole 751 are formed through a single process step, which is favorable to simplify the fabrication process steps, thereby saving the fabrication cost of the memory device 10.

With continued reference to FIG. 21, after forming the second deck structure 720 and before forming the first connection hole 230, the fabrication method comprises: removing part of the second deck structure 720 to form a second connection hole 722, wherein the second connection hole 722 is located in the second region 102 of the second deck structure 720, and the second connection hole 722 and the first connection hole 712 jointly constitute a connection hole 730.

In this operation, the second connection hole 722 may extend through the second deck structure 720 to the first connection hole 712. The second connection hole 722 may be formed through any suitable processes. For example, a patterned photoresist layer may be formed on the second deck structure 720. The patterned photoresist layer can expose a part of the second deck structure 720 for forming the second connection hole 722. A suitable etching process may be performed to remove the part of the second deck structure 720 for forming the second connection hole 722. For example, the etching process may include a dry etching process.

After forming the second connection hole 722, the patterned photoresist layer on the second deck structure 720 may be removed, for example, a surface of the second deck structure 720 may be planarized by chemical mechanical polishing (CMP) to remove the patterned photoresist layer on the second deck structure 720.

In some examples, the operation of removing part of the second deck structure 720 to form the second connection hole 722 further comprises: forming a second gate slit 744 that is located in the first region 101 of the second deck structure 720, wherein the second gate slit 744 and the first gate slit 743 jointly constitute a gate slit 760.

In this operation, with continued reference to FIG. 21, a second channel hole 752 may be also formed, the second gate slit is located between the second channel hole 752 and the second connection hole 722, and both the second channel hole 752 and the second gate slit are located in the first region 101 of the second deck structure 720. The second connection hole 722, the second gate slit and the second channel hole 752 may be formed through a single process step, for example, through a dry etching process. The second connection hole 722, the second gate slit and the second channel hole 752 are formed through a single process step, which is favorable to simplify the fabrication process steps, thereby saving the fabrication cost of the memory device 10.

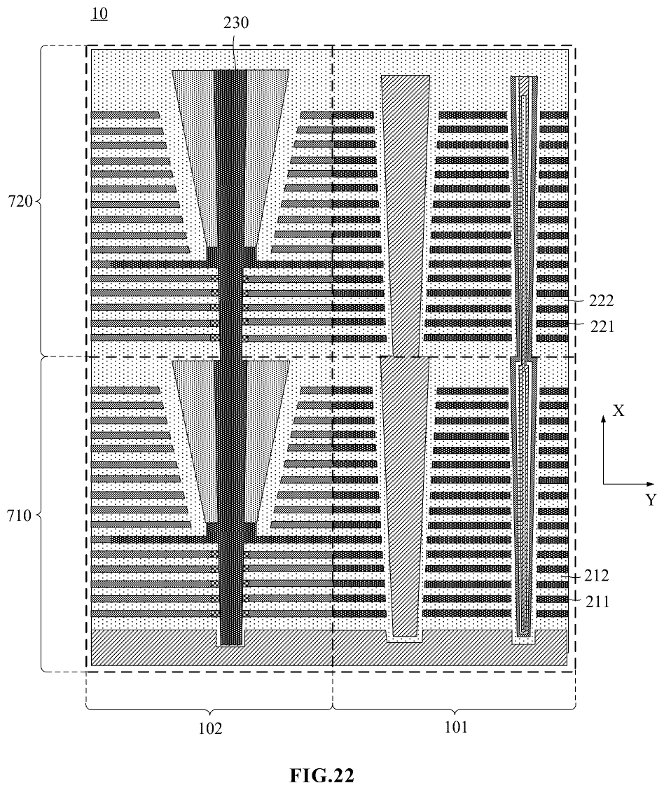

After forming the second deck structure 720 and before forming the first connection structure 230, as shown in FIGS. 21 and 22, the fabrication method further comprises: replacing the first sacrificial layer 711 with the first gate layer 211 and replacing the second sacrificial layer 721 with the second gate layer 221.

As shown in FIGS. 21 and 22, forming the first connection structure 230 comprises: depositing a conductive material in the connection hole 730 to form the first connection structure 230. In an example, the conductive material includes, but is not limited to, one or a combination of tungsten (W), cobalt (Co), copper (Cu), aluminum (Al), polysilicon, doped silicon, and silicides, or may include other suitable conductive materials.

The deposition process includes, but is not limited to, one or more of physical vapor deposition (PVD), chemical vapor deposition (CVD), and atomic layer deposition (ALD).

According to the fabrication method in this example, the first connection hole 712, the first gate slit and the first channel hole 751 may be formed through a single process step, and the second connection hole 722, the second gate slit and the second channel hole 752 are formed through a single process step, which is favorable to simplify the fabrication process steps, thereby saving the fabrication cost of the memory device 10.

In some examples, with reference to FIGS. 22 and 23, after forming the first deck structure 710 and before removing part of the first deck structure 710, as shown in FIG. 23, the fabrication method further comprises: forming a first groove 713 that is located in the second region 102 of the first deck structure 710 and extends through part of the first deck structure 710 along the first direction X, wherein the second region 102 of the first deck structure 710 comprises a plurality of third dielectric layers 271 and a plurality of fourth dielectric layers 272 stacked alternately along the first direction X, and at least one of the plurality of third dielectric layers 271 is connected with the first sacrificial layer 711.

In this operation, with continued reference to FIG. 23, the third dielectric layer 271 and the first sacrificial layer 711 may be a film layer formed by a single patterning process. The fourth dielectric layer 272 and the first dielectric layer 212 may be a film layer formed by a single patterning process. The patterning process refers to a process that can form at least one pattern with a certain shape. For example, a thin film is formed on a substrate by any one of multiple film formation processes such as deposition, spraying, sputtering, etc., and is then patterned to form a film layer containing at least one pattern, which is referred to as the pattern layer. Patterning steps include photoresist coating, exposure, development, etching, and photoresist stripping, etc.

With reference to FIGS. 23, 24, 25 and 26, after forming the first groove 713, the fabrication method further comprises: forming a first connection sacrificial layer 714.

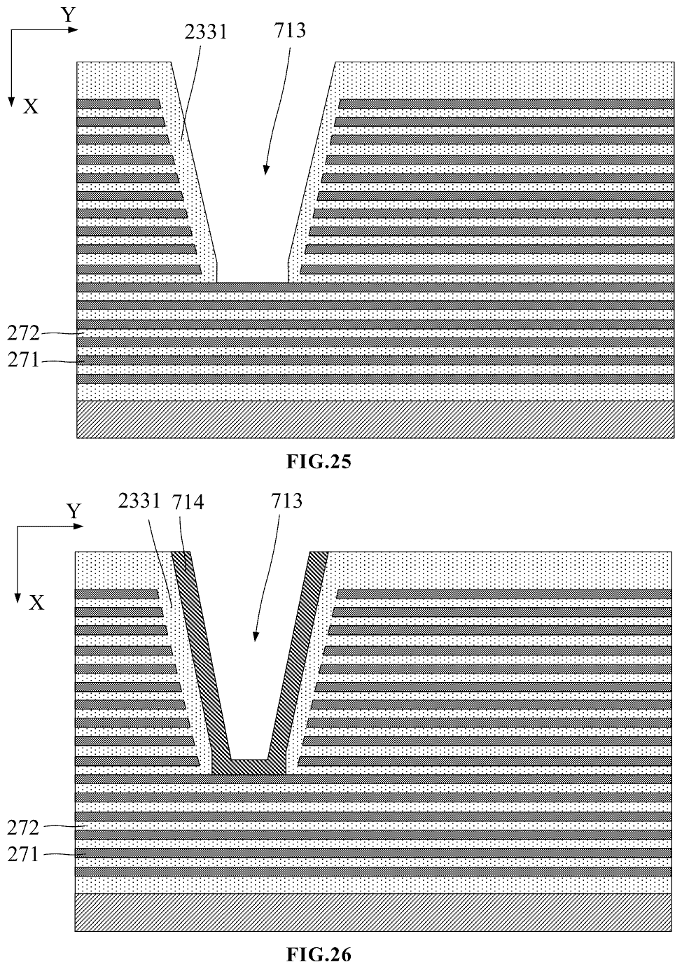

In this operation, with reference to FIGS. 24 and 25, forming the first connection sacrificial layer 714 comprises: forming a first isolation sub-layer 2331 that covers a wall of the first groove 713. In an example, an isolation material may be deposited in the first groove 713, wherein the isolation material includes, for example, one or a combination of silicon oxide, silicon nitride, and a high dielectric constant insulation material, and may also include other isolation materials. After depositing the isolation material in the first groove 713, the isolation material at the bottom of the first groove 713 and the fourth dielectric layer 272 at the bottom of the first groove 713 may be removed to form the first isolation sub-layer 2331 that covers the wall of the first groove 713, to expose the third dielectric layer 271.

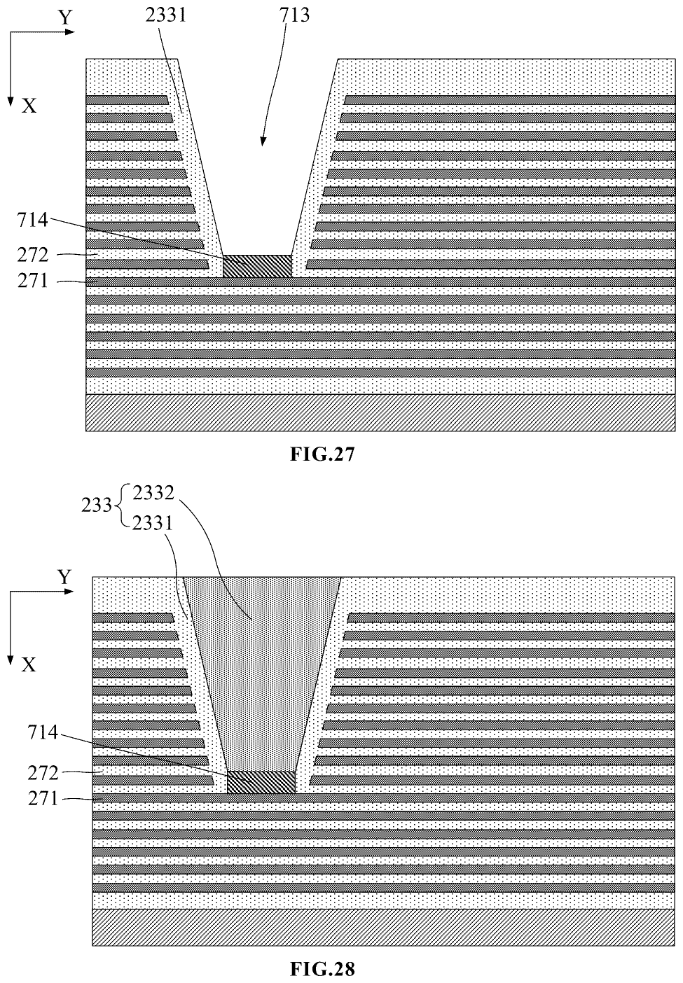

With reference to FIGS. 26 and 27, after forming the first isolation sub-layer 2331, a dielectric material is deposited in the first groove 713 and covers the bottom of the first groove 713. Ion implantation is performed on the dielectric material covering the bottom of the first groove 713 to remove the dielectric material covering the wall of the first groove 713, to form the first connection sacrificial layer 714. The first connection sacrificial layer 714 covers the bottom of the first groove 713 and is in contact with the third dielectric layer 271.

With reference to FIG. 28, after forming the first connection sacrificial layer 714, the fabrication method further comprises: forming a first isolation layer 233 that is located in the first groove 713. In this operation, as shown in FIG. 28, forming the first isolation layer 233 comprises: forming a second isolation sub-layer 2332 in the first groove 713. An isolation material may be deposited in the first groove 713 using one or more thin film deposition processes including but not limited to PVD, CVD and ALD to form the second isolation sub-layer 2332. The second isolation sub-layer 2332 and the first isolation sub-layer 2331 jointly constitute the first isolation layer 233.

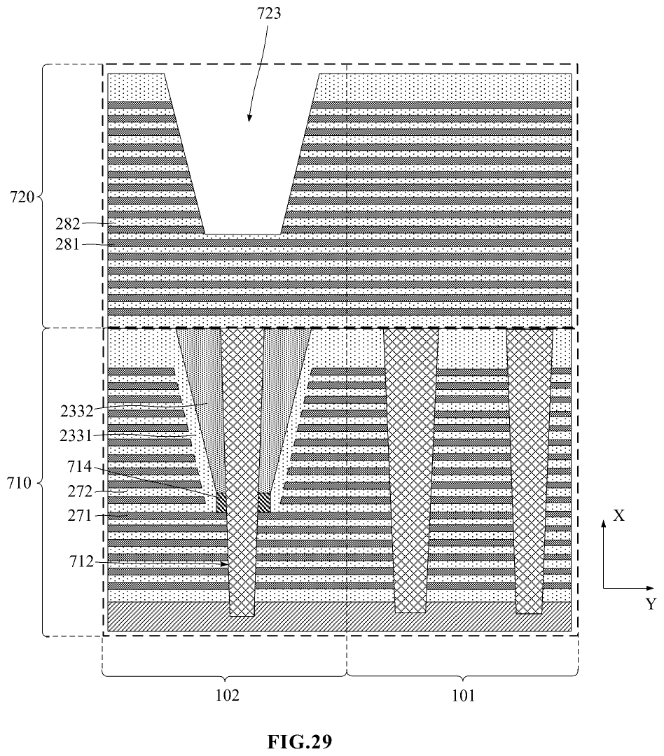

In some examples, as shown in FIG. 29, after forming the first isolation layer 233, part of the first deck structure 710 is removed to form the first connection hole 712, wherein removing part of the first deck structure 710 comprises: removing the first isolation layer 233, the first connection sacrificial layer 714, and the plurality of third dielectric layers 271 and the plurality of fourth dielectric layers 272 stacked together, to form the first connection hole 712.

In this operation, part of the first isolation layer 233, part of the first connection sacrificial layer 714, and part of the plurality of third dielectric layers 271 and the plurality of fourth dielectric layers 272 stacked together may be removed using an etching process to form the first connection hole 712. The etching process comprises a dry etching process or a wet etching process.

As shown in FIG. 29, after forming the first connection hole 712, a sacrificial material may be filled in the first connection hole 712 to facilitate subsequent formation of the second deck structure 720 on the first deck structure 710.

In some examples, as shown in FIG. 29, after filling the sacrificial material in the first connection hole 712, the second deck structure 720 may be formed on the first deck structure 710 using one or more thin film deposition processes, including but not limited to PVD, CVD and ALD.

In some examples, as shown in FIG. 29, after forming the second deck structure 720 and before removing part of the second deck structure 720, the fabrication method further comprises: forming a second groove 723 that is located in the second region 102 of the second deck structure 720 and extends through part of the second deck structure 720 along the first direction X, wherein the second region 102 of the second deck structure 720 comprises a plurality of fifth dielectric layers 281 and a plurality of sixth dielectric layers 282 stacked alternately along the first direction X, and at least one of the plurality of fifth dielectric layers 281 is connected with the second sacrificial layer 721.

In this operation, with continued reference to FIG. 29, the fifth dielectric layer 281 and the second sacrificial layer 721 may be a film layer formed by a single patterning process. The sixth dielectric layer 282 and the second dielectric layer 222 may be a film layer formed by a single patterning process.

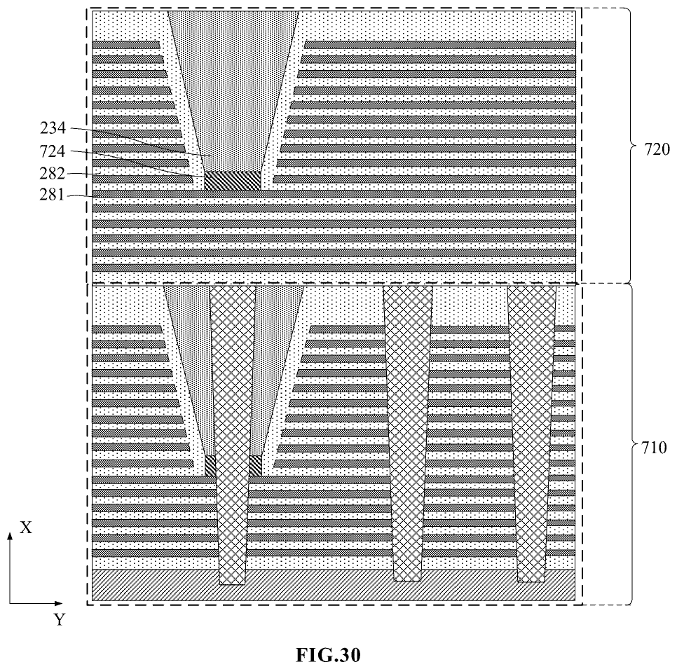

After forming the second groove 723, as shown in FIG. 30, the fabrication method further comprises: forming a second connection sacrificial layer 724. The second connection sacrificial layer 724 covers a bottom of the second groove 723, and is in contact with the fifth dielectric layer 281. A specific fabrication method of the second connection sacrificial layer 724 may be referred to the above fabrication method of the first connection sacrificial layer 714, which is no longer repeated herein.

After forming the second connection sacrificial layer 724, the fabrication method further comprises: forming a second isolation layer 234 that is located in the second groove 723.

Removing part of the second deck structure 720 to form the second connection hole 722 comprises: removing the second isolation layer 234, the second connection sacrificial layer 724, and the plurality of fifth dielectric layers 281 and the plurality of sixth dielectric layers 282 stacked together, to form the second connection hole 722.

In this operation, part of the second isolation layer 234, part of the second connection sacrificial layer 724, and part of the plurality of fifth dielectric layers 281 and the plurality of sixth dielectric layers 282 stacked together may be removed using an etching process to form the second connection hole 722. The etching process comprises a dry etching process or a wet etching process.

After forming the second connection hole 722, the sacrificial material in the first connection hole 712 may be removed, such that the first connection hole 712 and the second connection hole 722 are connected, and the first connection hole 712 and the second connection hole 722 jointly constitute the connection hole 730. In an example, when the sacrificial material comprises carbon, a process of removing the sacrificial material in the first connection hole 712 may include ashing, to removing all of the sacrificial material in the first connection hole 712.

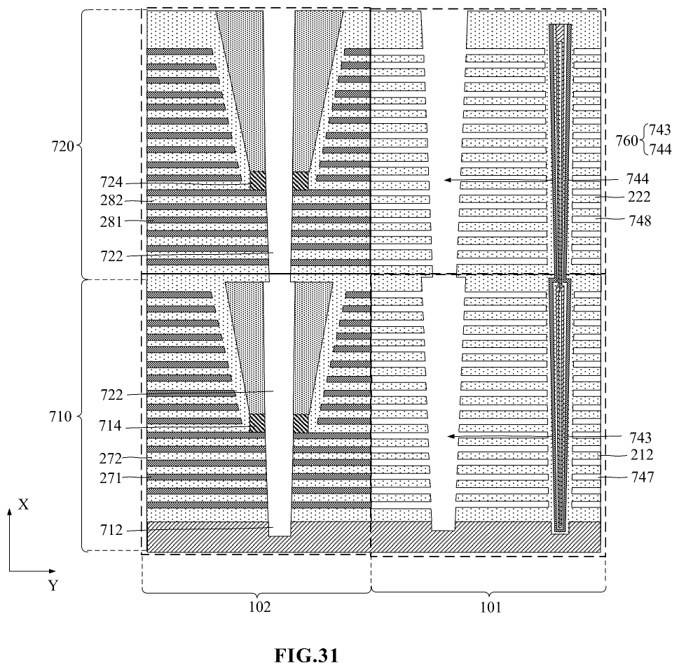

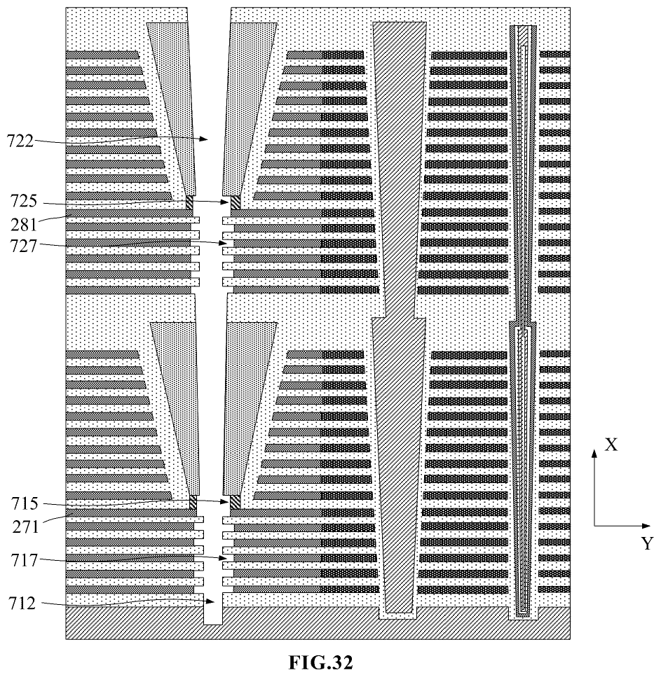

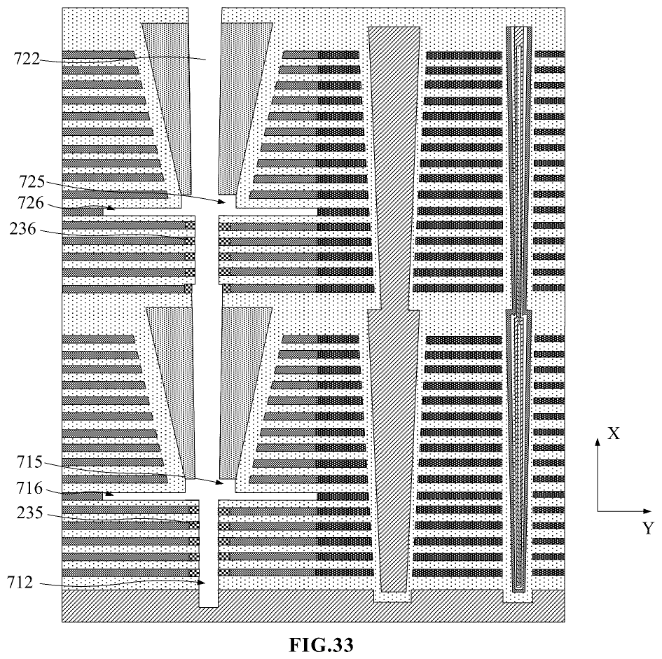

In some examples, as shown in FIGS. 31, 32, 33 and 34, forming the first connection structure 230 in the connection hole comprises: removing the first connection sacrificial layer 714 and the second connection sacrificial layer 724 to form a first recessed space 715 and a second recessed space 725, wherein the first recessed space 715 and the first connection hole 712 are connected, and the second recessed space 725 and the second connection hole 722 are connected.

In this operation, with reference to FIGS. 31 and 32, the first connection sacrificial layer 714 and the second connection sacrificial layer 724 may be removed by injecting an etchant into the connection hole 730. An etching rate of the etchant for the third dielectric layer 271 and the fifth dielectric layer 281 is greater than an etching rate for the fourth dielectric layer 272 and the sixth dielectric layer 282. Moreover, an etching rate of the etchant for the first connection sacrificial layer 714 and the second connection sacrificial layer 724 may be approximately the same as the etching rate of the etchant for the third dielectric layer 271 and the fifth dielectric layer 281, or the etching rate of the etchant for the first connection sacrificial layer 714 and the second connection sacrificial layer 724 may be less than the etching rate of the etchant for the third dielectric layer 271 and the fifth dielectric layer 281.

Thus, in this operation, part of the third dielectric layers 271 and part of the fifth dielectric layers 281 may be also removed while removing the first connection sacrificial layer 714 and the second connection sacrificial layer 724 to form a third recessed space 717 and a fourth recessed space 727, wherein the third recessed space 717 and the first connection hole 712 are connected, and the fourth recessed space 727 and the second connection hole 722 are connected.

Since the first connection sacrificial layer 714 is in contact with one of the third dielectric layers 271, and the second connection sacrificial layer 724 is in contact with one of the fifth dielectric layers 281, in the first direction X, the thickness of the first connection sacrificial layer 714 and one of the third dielectric layers 271 is greater than the thickness of one of the third dielectric layers 271; and in the first direction X, the thickness of the second connection sacrificial layer 724 and one of the fifth dielectric layers 281 is greater than the thickness of one of the fifth dielectric layers 281. Therefore, after injecting the etchant into the connection hole 730, in the second direction Y, the etched length of the third dielectric layer 271 in contact with the first connection sacrificial layer 714 is less than the etched length of the other third dielectric layers 271; and in the second direction Y, the etched length of the fifth dielectric layer 281 in contact with the second connection sacrificial layer 724 is less than the etched length of the other fifth dielectric layers 281.

The first recessed space 715 and the second recessed space 725 are formed where the first connection sacrificial layer 714 and second connection sacrificial layer 724 are removed, wherein the first recessed space 715 and the first connection hole 712 are connected, and the second recessed space 725 and the second connection hole 722 are connected. It is to be noted that the first connection sacrificial layer 714 and the second connection sacrificial layer 724 may be removed partially or completely.

It is to be noted that the first isolation layer 233 may protect the third dielectric layer 271 and the fourth dielectric layer 272 surrounding the first isolation layer 233 from being etched, and the second isolation layer 234 may protect the fifth dielectric layer 281 and the sixth dielectric layer 282 surrounding the second isolation layer 234 from being etched. Thus, in this operation, an etching process may be used, and an etchant with a high etching rate for the third dielectric layer 271 and the fifth dielectric layer 281 and a low etching rate for the fourth dielectric layer 272 and the sixth dielectric layer 282 (or no etching for the fourth dielectric layer 272 and the sixth dielectric layer 282) may be selected, to remove part of the third dielectric layers 271 exposed in the first connection hole 712 and part of the fifth dielectric layers 281 exposed in the second connection hole 722 to form the third recessed space 717 and the fourth recessed space 727.

Moreover, with reference to FIGS. 32 and 33, a third isolation layer 235 may be formed in the third recessed space 717 and a fourth isolation layer 236 may be formed in the fourth recessed space 727 using one or more thin film deposition processes including but not limited to PVD, CVD and ALD, to protect the third dielectric layer 271 and the fifth dielectric layer 281 from being etched in a subsequent fabrication process.

In this operation, it is to be noted that, in the first direction X, the thickness of the first connection sacrificial layer 714 and one of the third dielectric layers 271 is greater than the thickness of one of the third dielectric layers 271; and in the first direction X, the thickness of the second connection sacrificial layer 724 and one of the fifth dielectric layers 281 is greater than the thickness of one of the fifth dielectric layers 281. Therefore, when the third isolation layer 235 is formed in the third recessed space 717 and the fourth isolation layer 236 is formed in the fourth recessed space 727, the third isolation layer 235 formed on the third dielectric layer 271 exposed to the first recessed space 715 is thin, and the fourth isolation layer 236 formed on the fifth dielectric layer 281 exposed to the second recessed space 725 is thin. The third isolation layer 235 formed on the third dielectric layer 271 exposed to the first recessed space 715 and the fourth isolation layer 236 formed on the fifth dielectric layer 281 exposed to the second recessed space 725 may be removed by a small amount of etchant. Moreover, the third isolation layer 235 formed in the third recessed space 717 and the fourth isolation layer 236 formed in the fourth recessed space 727 are retained.

After forming the first recessed space 715 and the second recessed space 725, as shown in FIGS. 32 and 33, the fabrication method further comprises: removing the third dielectric layer 271 exposed to the first recessed space 715 and the fifth dielectric layer 281 exposed to the second recessed space 725 to form a first filling space 716 and a second filling space 726, wherein the first filling space 716 and the first recessed space 715 are connected, and the second filling space 726 and the second recessed space 725 are connected.

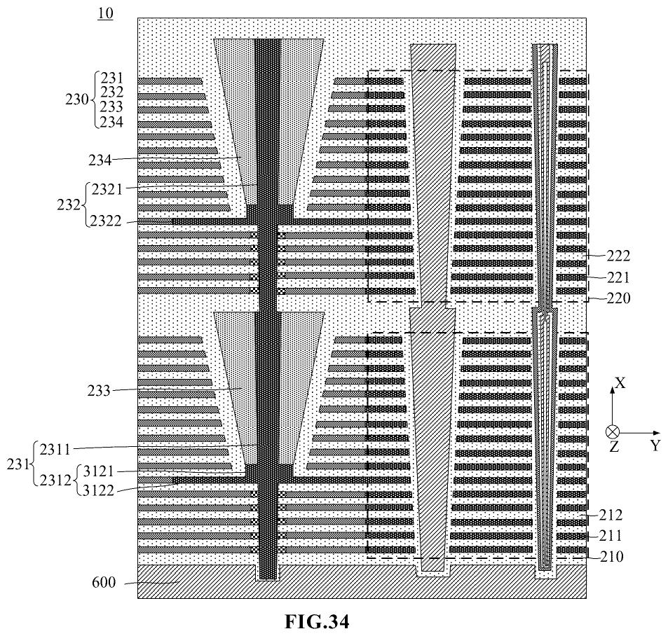

With reference to FIGS. 33 and 34, after forming the first filling space 716 and the second filling space 726, the fabrication method further comprises: filling a conductive material in the connection hole 730 to form the first connection structure 230.

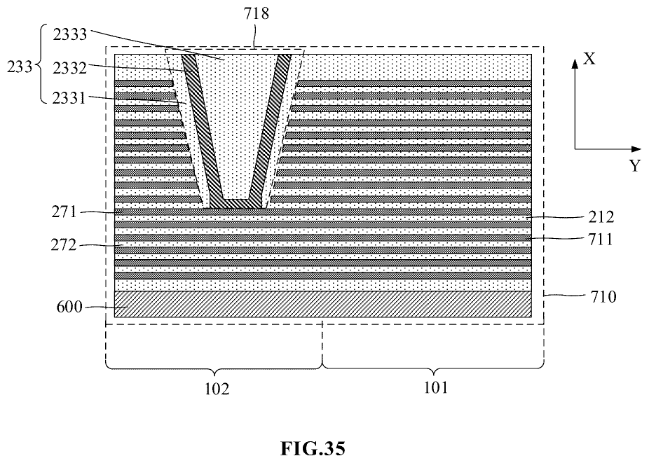

Some other examples of the present disclosure further provide a fabrication method of a memory device. As shown in FIG. 35, after forming the first deck structure 710 and before removing part of the first deck structure 710, the fabrication method further comprises: forming a third groove 718 that is located in the second region 102 of the first deck structure 710 and extends through part of the first deck structure 710 along the first direction X, wherein the second region 102 of the first deck structure 710 comprises a plurality of third dielectric layers 271 and fourth dielectric layers 272 stacked alternately along the first direction, and at least one of the plurality of third dielectric layers 271 is connected with the first sacrificial layer 711.

In this operation, the third dielectric layer 271 and the first sacrificial layer 711 may be a film layer formed by a single patterning process. The fourth dielectric layer 272 and the first dielectric layer 212 may be a film layer formed by a single patterning process.

After forming the third groove 718, as shown in FIG. 35, the fabrication method further comprises: forming a first isolation sub-layer 2331 that covers a bottom of the third groove 718.

In this operation, after depositing an isolation material in the third groove 718, the isolation material at the bottom of the third groove 718 may be removed to form the first isolation sub-layer 2331.

After forming the first isolation sub-layer 2331, as shown in FIG. 35, the fabrication method further comprises: forming a second isolation sub-layer 2332, wherein the second isolation sub-layer 2332 covers the bottom of the third groove 718 and is in contact with the third dielectric layer 271, and also covers a side of the first isolation sub-layer 2331.

After forming the second isolation sub-layer 2332, as shown in FIG. 35, the fabrication method further comprises: forming a third isolation sub-layer 2333 in the third groove 718, wherein the third isolation sub-layer 2333 covers the second isolation sub-layer 2332, and the first isolation sub-layer 2331, the second isolation sub-layer 2332 and the third isolation sub-layer 2333 jointly constitute the first isolation layer 233.

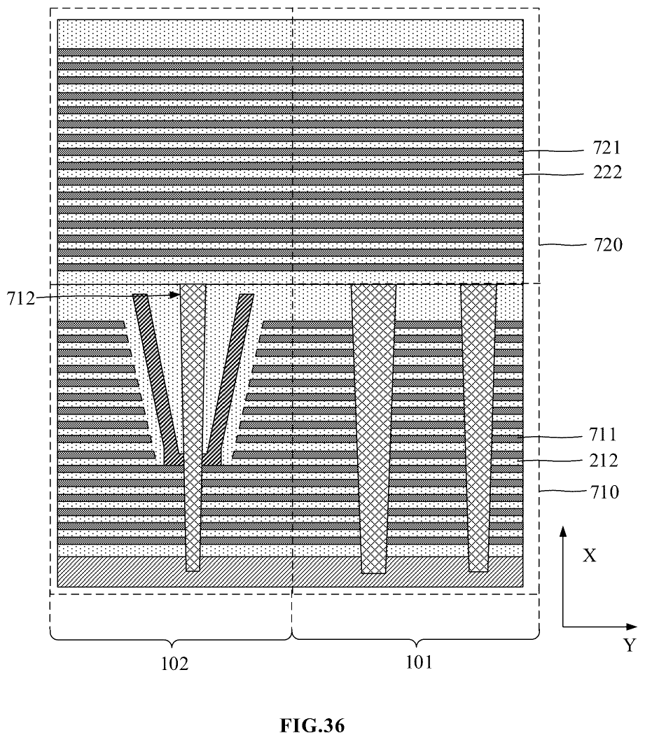

After forming the second isolation sub-layer 2332, with reference to FIG. 36, the fabrication method further comprises: removing part of the first deck structure 710 to form a first connection hole 712. The first connection hole 712 extends through the first deck structure 710, and is located in the first region 101 of the first deck structure 710.

As shown in FIGS. 35 and 36, this operation comprises: removing the second isolation sub-layer 2332, the third isolation sub-layer 2333, the plurality of third dielectric layers 271 and the plurality of fourth dielectric layers 272 to form the first connection hole 712. After forming the first connection hole 712, a sacrificial material may be deposited in the first connection hole 712 to facilitate subsequent formation of the second deck structure 720 on the first deck structure 710.

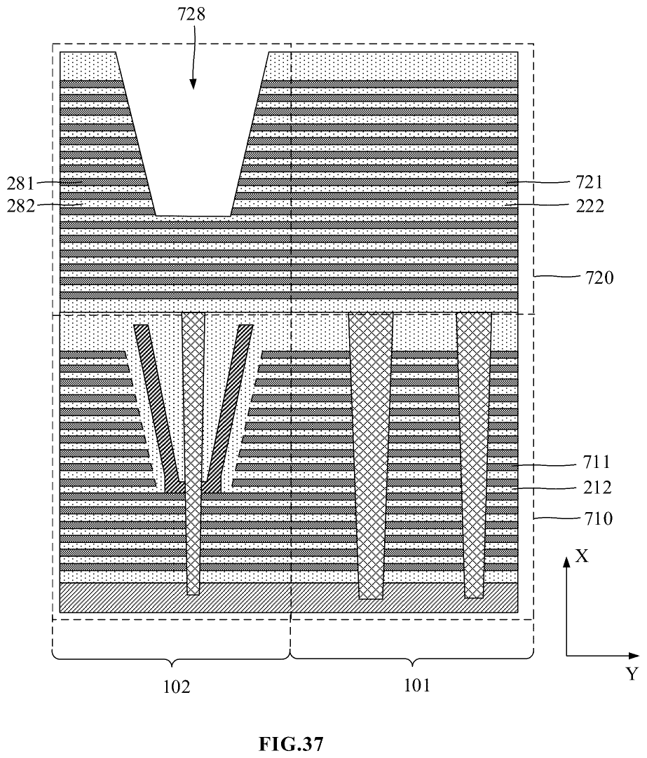

In some examples, as shown in FIG. 37, after forming the second deck structure 720 and before removing part of the second deck structure 720, the fabrication method further comprises: forming a fourth groove 728 that is located in the second region 102 of the second deck structure 720 and extends through part of the second deck structure 720 along the first direction X, wherein the second region 102 of the second deck structure 720 comprises a plurality of fifth dielectric layers 281 and a plurality of sixth dielectric layers 282 stacked alternately along the first direction X, and at least one of the plurality of fifth dielectric layers 281 is connected with the second sacrificial layer 721.

In this operation, with continued reference to FIG. 37, the fifth dielectric layer 281 and the second sacrificial layer 721 may be a film layer formed by a single patterning process. The sixth dielectric layer 282 and the second dielectric layer 222 may be a film layer formed by a single patterning process.

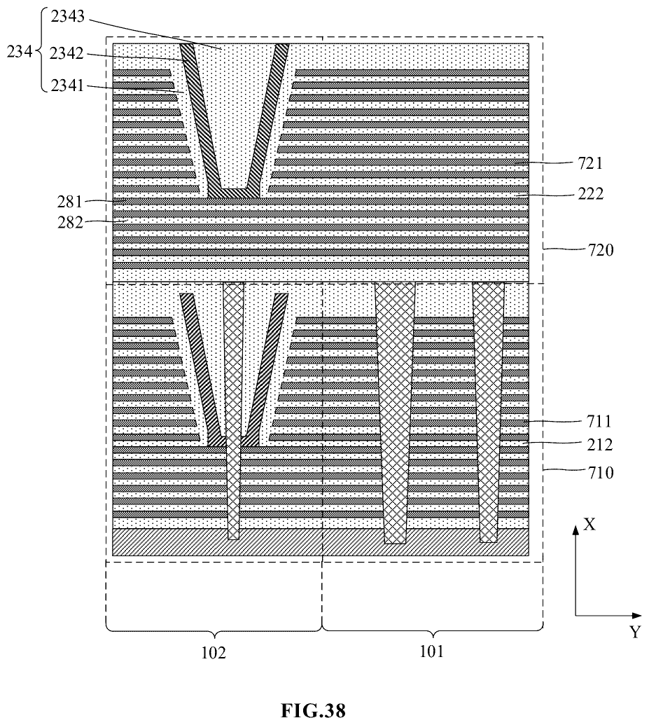

After forming the fourth groove 728, with reference to FIGS. 37 and 38, the fabrication method further comprises: forming a fourth isolation sub-layer 2341 that covers a wall of the fourth groove 728. A fifth isolation sub-layer 2342 is formed, wherein the fourth isolation sub-layer 2342 covers a bottom of the fourth groove 728 and the fourth isolation sub-layer 2341 and is in contact with the fifth dielectric layer 281. A sixth isolation sub-layer 2343 is formed in the fourth groove 728, wherein the sixth isolation sub-layer 2343 covers the fifth isolation sub-layer 2342, and the fourth isolation sub-layer 2341, the fifth isolation sub-layer 2342 and the sixth isolation sub-layer 2343 jointly constitute the second isolation layer 234.

In this operation, a method of forming the fourth isolation sub-layer 2341, the fifth isolation sub-layer 2342 and the sixth isolation sub-layer 2343 may be referred to a fabrication method of the first isolation sub-layer 2331, the second isolation sub-layer 2332 and the third isolation sub-layer 2333 in some examples above, which is no longer repeated herein.

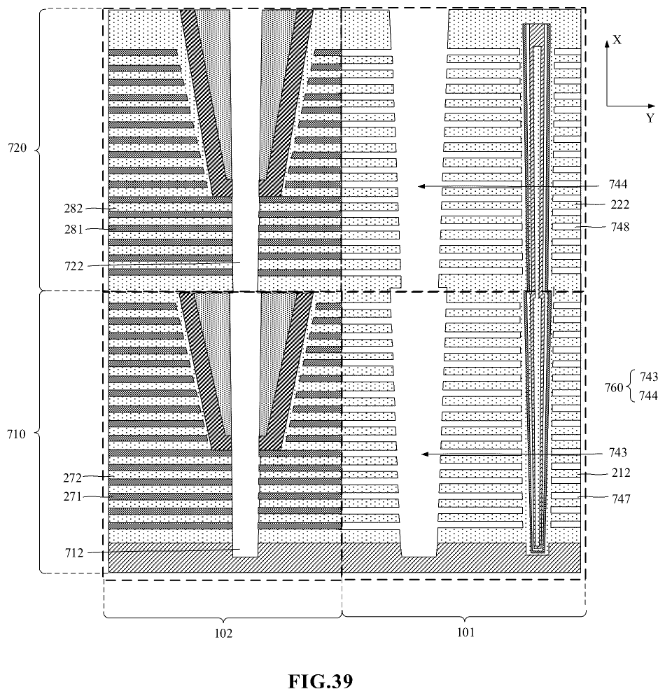

With reference to FIGS. 38 and 39, after forming the second isolation layer 234, the fabrication method further comprises: removing part of the second deck structure 720 to form the second connection hole 722.

In this operation, removing part of the second deck structure 720 comprises: removing the fifth isolation sub-layer 2342, the sixth isolation sub-layer 2343, the plurality of fifth dielectric layers 281 and the plurality of sixth dielectric layers 282 to form the second connection hole 722.

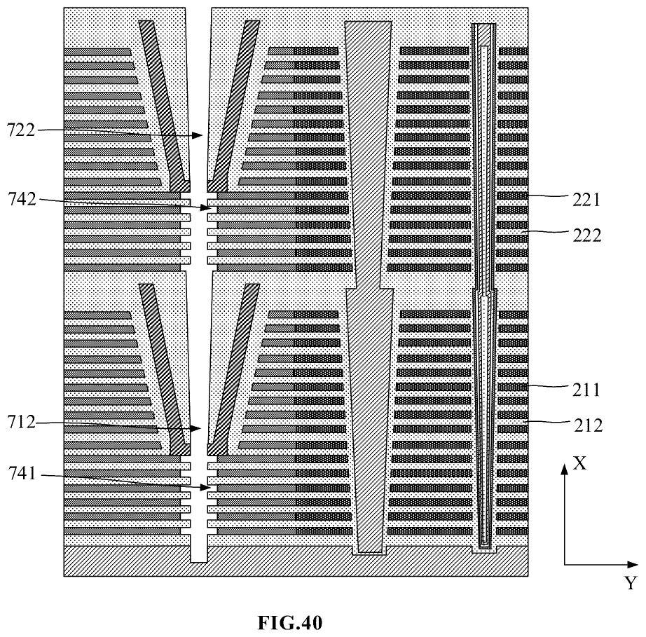

With reference to FIGS. 39 and 40, in the operation of removing part of the first deck structure 710 to form the first connection hole 712, the first gate slit 743 may be formed at the same time and is located in the first region 101 of the first deck structure 710. In the operation of removing part of the second deck structure 720 to form the second connection hole 722, the second gate slit 744 may be formed at the same time and is located in the first region 101 of the second deck structure 720.

After forming the second gate slits 744, the first sacrificial layer 711 may be replaced with the first gate layer 211, and the second sacrificial layer 721 may be replaced with the second gate layer 221.

As shown in FIGS. 39 and 40, this operation comprises: injecting an etchant into the gate slit 760 to remove the first sacrificial layer 711 and the second sacrificial layer 721, to form a fifth filling space 747 and a sixth filling space 748. A gate material is deposited in the fifth filling space 747 and the sixth filling space 748 to form the first gate layer 211 and the second gate layer 221.

In some examples, with reference to FIGS. 35, 40, 41 and 42, forming the first connection structure 230 in the connection hole 730 comprises: removing the second isolation sub-layer 2332 at the bottom of the third groove 718 and the fifth isolation sub-layer 2342 at the bottom of the fourth groove 728 to form a fifth recessed space 719 and a sixth recessed space 729, wherein the fifth recessed space 719 and the first connection hole 712 are connected, and the sixth recessed space 729 and the second connection hole 722 are connected.

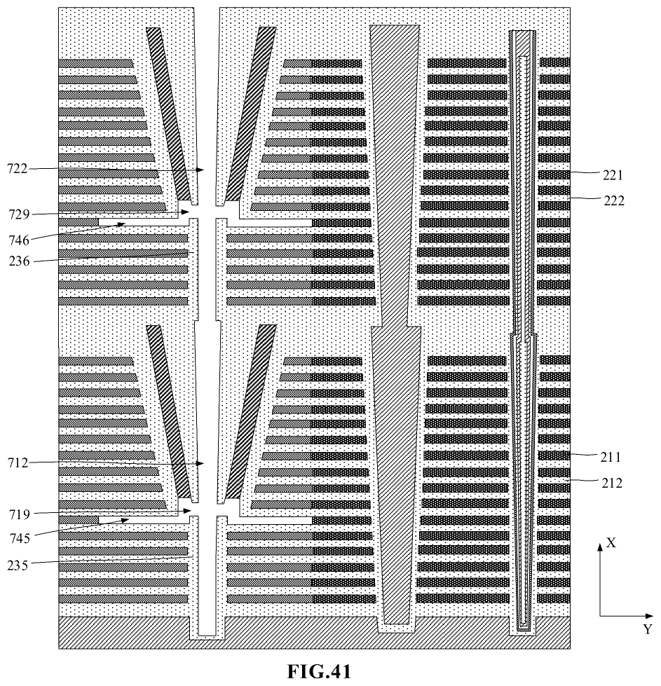

With reference to FIGS. 40 and 41, before removing the second isolation sub-layer 2332 at the bottom of the third groove 718 and the fifth isolation sub-layer 2342 at the bottom of the fourth groove 728, this operation further comprises: removing part of the second dielectric layer 222 and part of the fourth dielectric layer 272 to form a seventh recessed space 741 and an eighth recessed space 742, wherein the seventh recessed space 741 and the first connection hole 712 are connected, and the eighth recessed space 742 and the second connection hole 722 are connected. A third isolation layer 235 is formed in the seventh recessed space 741, and a fourth isolation layer 236 is formed in the eighth recessed space 742, to protect the second dielectric layer 222 and the fourth dielectric layer 272 against damage in a subsequent etching process.

As shown in FIG. 41, after forming the fifth recessed space 719 and the sixth recessed space 729, the fabrication method further comprises: removing the third dielectric layer 271 exposed to the fifth recessed space 719 and the fifth dielectric layer 281 exposed to the sixth recessed space 729 to form a third filling space 745 and a fourth filling space 746, wherein the third filling space 745 and the fifth recessed space 719 are connected, and the fourth filling space 746 and the sixth recessed space 729 are connected.

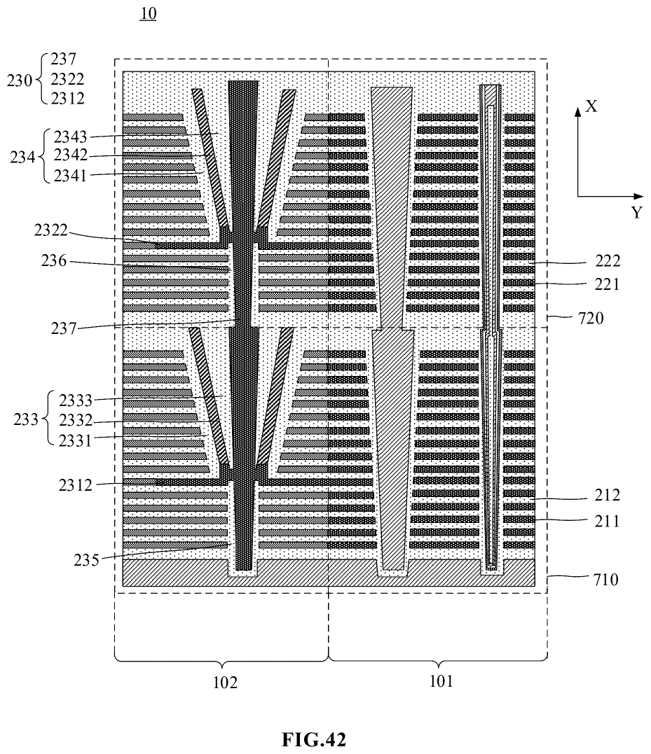

As shown in FIGS. 41 and 42, after forming the third filling space 745 and the fourth filling space 746, the fabrication method further comprises: filling a conductive material in the connection hole 730 to form the first connection structure 230.

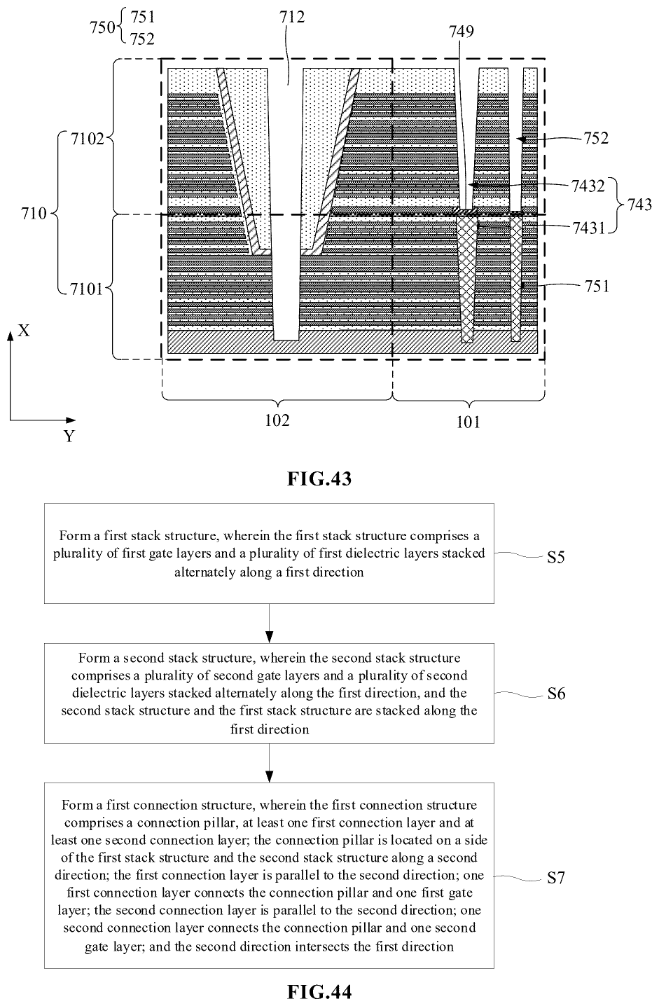

In some examples, as shown in FIG. 43, forming the first deck structure 710 comprises: forming a first deck sub-structure 7101 that comprises a first gate sub-slit 7431 and a first channel hole 751.

In this operation, the first gate sub-slit 7431 and the first channel hole 751 may be formed on the first deck sub-structure 7101 through an etching process. Moreover, the first gate sub-slit 7431 and the first channel hole 751 are located in the first region 101 of the first deck sub-structure 7101.

With continued reference to FIG. 43, after forming the first gate sub-slit 7431 and the first channel hole 751, a sacrificial material may be filled in the first gate sub-slit 7431 and the first channel hole 751, such that a second deck sub-structure 7102 continues to be formed on the first deck sub-structure 7101 in a subsequent fabrication step.

With continued reference to FIG. 43, after filling the sacrificial material in the first gate sub-slit 7431 and the first channel hole 751, the fabrication method further comprises: forming an etching stop layer 749 on the first gate sub-slit 7431 and the first channel hole 751.

The second deck sub-structure 7102 is formed, wherein the second deck sub-structure 7102 is located on a side of the etching stop layer 749 away from the first gate sub-slit 7431 and the first channel hole 751, and the second deck sub-structure 7102 and the first deck sub-structure 7101 jointly constitute the first deck structure 710.

The operation of removing part of the first deck structure 710 to form the first connection hole 712 further comprises: forming a second gate sub-slit 7432 and a second channel hole 752, wherein the second gate sub-slit 7432 and the first gate sub-slit jointly constitute the first gate slit, the second channel hole 752 and the first channel hole 751 jointly constitute a channel hole 750, and the first gate slit and the channel hole 750 are located in the first region 101 of the first deck structure 710.

As shown in FIG. 43, the first connection hole 712, the second gate sub-slit 7432 and the second channel hole 752 are formed in the operation of removing part of the first deck structure 710. However, the first connection hole 712 extends through the first deck sub-structure 7101 and the second deck sub-structure 7102, while the second gate sub-slit 7432 and the second channel hole 752 only extend through the second deck sub-structure 7102, that is, an etching depth of the first connection hole 712 is different from an etching depth of the second gate sub-slit 7432, and an etching depth of the first connection hole 712 is different from an etching depth of the second channel hole 752. Thus, in this operation, before forming the second deck sub-structure 7102, the etching stop layer 749 is formed on the first gate sub-slit 7431 and the first channel hole 751, which is favorable to protect the first gate sub-slit and the first channel hole 751 from being etched during the formation of the first connection hole 712, the second gate sub-slit 7432 and the second channel hole 752, so as to protect the structure shape of the channel hole 750.

In this example, the operation of forming the first deck structure 710 may comprise: forming the first deck sub-structure 7101 and the second deck sub-structure 7102, and so on. For the second deck structure 720, two or more deck sub-structures may be formed by the same fabrication step.

Some examples of the present disclosure further provide another fabrication method of a memory device. This fabrication method of the memory device is illustrated below in conjunction with FIGS. 23-44.

FIG. 44 is a flow diagram of a fabrication method of a memory device according to some other examples. As shown in FIG. 44, the fabrication method of the memory device comprises: S5-S7.

At S5, a first stack structure is formed, wherein the first stack structure comprises a plurality of first gate layers and a plurality of first dielectric layers stacked alternately along a first direction.

In this operation, with reference to FIG. 42, the plurality of first gate layers 211 and the plurality of first dielectric layers 212 stacked alternately along the first direction X may be formed using one or more thin film deposition processes including, but not limited to, PVD, CVD and ALD.

At S6, a second stack structure is formed, wherein the second stack structure comprises a plurality of second gate layers and a plurality of second dielectric layers stacked alternately along the first direction, and the second stack structure and the first stack structure are stacked along the first direction.

In this operation, with reference to FIG. 42, the plurality of second gate layers 221 and the plurality of second dielectric layers 222 stacked alternately along the first direction X may be formed on the first stack structure 210 using one or more thin film deposition processes including, but not limited to, PVD, CVD and ALD.

At S7, a first connection structure is formed, wherein the first connection structure comprises a connection pillar, at least one first connection layer and at least one second connection layer; the connection pillar is located on a side of the first stack structure and the second stack structure along the second direction; the first connection layer is parallel to a second direction; one first connection layer connects the connection pillar and one first gate layer; the second connection layer is parallel to the second direction; one second connection layer connects the connection pillar and one second gate layer; and the second direction intersects the first direction.

In this operation, with reference to FIG. 42, the first connection structure 230 may be formed on a side of the first stack structure 210 and the second stack structure 220 along the second direction Y using an etching process and a deposition process, etc.

In an example, a composition material of the first connection structure 230 may include a conductive material that includes, but is not limited to, one or a combination of tungsten (W), cobalt (Co), copper (Cu), aluminum (Al), polysilicon, doped silicon, and silicides, or may be also other suitable conductive materials.

According to the memory device 10 fabricated by the above operations, one SD device may be connected with at least one first gate layer 211 and at least one second gate layer 221 through the first connection structure 230. One first gate layer 211 and one second gate layer 221 may share one first connection structure 230 and may share one SD device. Thus, when the memory device 10 has two stack structures (i.e., the first stack structure 210 and the second stack structure 220), compared with one first gate layer 211 being connected with one SD device through one gate line contact G-CNT and one second gate layer 221 being connected with one SD device through one gate line contact G-CNT, the number of the first connection structures 230 in this example is less than the number of the gate line contacts G-CNT, and the number of the SD devices in this example is also smaller, such that the footprint of the first connection structure 230 is smaller than the footprint of the gate line contact G-CNT, and meanwhile, the footprint of the SD device is also reduced, which is favorable to increase the storage density of the memory device 10.

In some examples, as shown in FIG. 23, forming the first stack structure 210 comprises: forming a first deck structure 710, wherein a first region of the first deck structure 710 comprises a plurality of first sacrificial layers 711 and a plurality of first dielectric layers 212 stacked alternately along the first direction and adjoins a second region 102 of the first deck structure 710, the second region 102 of the first deck structure 710 is located on a side of the first region 101 of the first deck structure 710 along the second direction Y, and the second direction Y intersects the first direction X.

In this operation, as shown in FIG. 23, the first dielectric layers 212 and the first sacrificial layers 711 may be formed alternately using a deposition process. In an example, a material of the first dielectric layer 212 may include silicon oxide, and a material of the first sacrificial layer 711 may include silicon nitride.

Forming the second stack structure 220 comprises: forming a second deck structure 720, wherein the second deck structure 720 and the first deck structure 710 are stacked along the first direction; a first region 101 of the second deck structure 720 comprises a plurality of second sacrificial layers 721 and a plurality of dielectric layers 222 stacked alternately along the first direction and adjoins a second region 102 of the second deck structure 720; and the second region 102 of the second deck structure 720 is located on a side of the first region 101 of the second deck structure 720 along the second direction Y.

In this operation, as shown in FIG. 21, for example, the second dielectric layers 222 and the second sacrificial layers 721 may be formed alternately on the first deck structure 710 using a deposition process. In an example, a material of the second dielectric layer 222 may include silicon oxide, and a material of the second sacrificial layer 721 may include silicon nitride.

After forming the first deck structure 710 and before forming the second deck structure 720, the fabrication method further comprises: removing part of the first deck structure 710 to form a first connection hole 712, wherein the first connection hole 712 is located in the second region 102 of the first deck structure 710.

In this operation, as shown in FIG. 21, for example, the first connection hole 712 may be formed using an etching process.

Part of the second deck structure 720 is removed to form a second connection hole 722, wherein the second connection hole 722 extends through the second region 102 of the second deck structure 720, and the second connection hole 722 and the first connection hole 712 jointly constitute a connection hole.

As shown in FIGS. 33 and 34, after forming the second deck structure 720, the fabrication method further comprises: forming a first filling space 716 and a second filling space 726, wherein the first filling space 716 is located in the second region 102 of the first deck structure 710, and the first filling space 716 and the first connection hole 712 are connected; the second filling space 726 is located in the second region 102 of the first deck structure 710, and the second filling space 726 and the second connection hole 722 are connected.

The process of forming the first filling space 716 and the second filling space 726 may be referred to some examples above, which is no longer repeated herein.

As shown in FIGS. 30, 31, 32 and 33, the first sacrificial layer 711 is replaced with the first gate layer 211, and the second sacrificial layer 721 is replaced with the second gate layer 221. At least one first gate layer 211 and the first filling space 716 are connected, and at least one second gate layer 221 and the second filling space 726 are connected.

The process of replacing the first sacrificial layer 711 with the first gate layer 211 and replacing the second sacrificial layer 721 with the second gate layer 221 may be referred to some examples above, which is no longer repeated herein.

As shown in FIGS. 33 and 34, forming the first connection structure 230 comprises: filling a conductive material in the connection hole 730 to form the first connection structure 230, wherein the conductive material filled in the connection hole 730 forms the connection pillar; the conductive material filled in the first filling space 716 forms the first connection layer 2312; and the conductive material filled in the second filling space 726 forms the second connection layer 2322. The first connection layer 2312 is parallel to the second direction; one first connection layer 2312 connects the connection pillar 237 and one first gate layer 211; the second connection layer 2322 is parallel to the second direction; one second connection layer 2322 connects the connection pillar 237 and one second gate layer 221; and the connection pillar, the first connection layer 2312 and the second connection layer 2322 jointly constitute the first connection structure 230.

According to the memory device 10 fabricated by the above operations, one SD device may be connected with at least one first gate layer 211 and at least one second gate layer 221 through the first connection structure 230. One first gate layer 211 and one second gate layer 221 may share one first connection structure 230 and may share one SD device, which is favorable to control the footprint of the second region 102 and increase the storage density of the memory device 10.

Some examples of the present disclosure further provide another fabrication method of a memory device. This fabrication method of the memory device is illustrated below in conjunction with FIGS. 21-46.

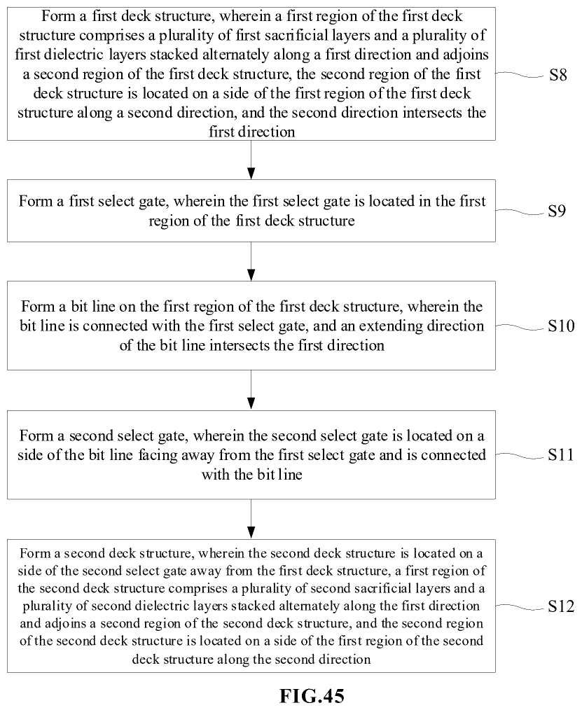

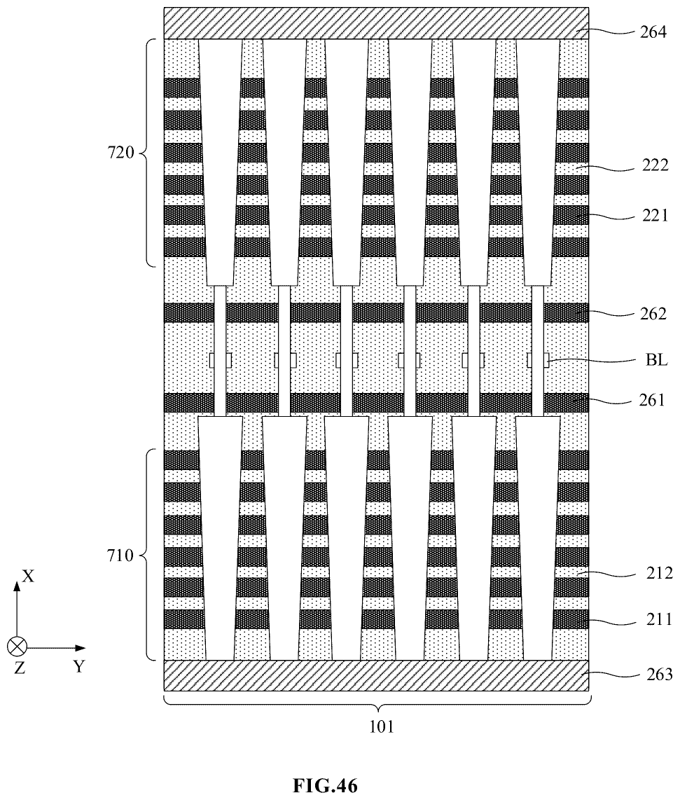

Some examples of the present disclosure further provide a fabrication method of a memory device. As shown in FIG. 45, the fabrication method comprises: S8-S12.

At S8, a first deck structure is formed, wherein a first region of the first deck structure comprises a plurality of first sacrificial layers and a plurality of first dielectric layers stacked alternately along a first direction and adjoins a second region of the first deck structure, the second region of the first deck structure is located on a side of the first region of the first deck structure along a second direction, and the second direction intersects the first direction.

In this operation, as shown in FIG. 23, the first dielectric layers 212 and the first sacrificial layers 711 may be formed alternately using a deposition process. In an example, a material of the first dielectric layer 212 may include silicon oxide, and a material of the first sacrificial layer 711 may include silicon nitride.

At S9, a first select gate is formed, wherein the first select gate is located in the first region of the first deck structure.

In this operation, with reference to FIG. 46, the first select gate 261 is formed on the first deck structure 710 and is located in the first region 101 of the first deck structure 710.

At S10, a bit line is formed in the first region of the first deck structure, wherein the bit line is connected with the first select gate, and an extending direction of the bit line intersects the first direction.

In this operation, with reference to FIG. 46, the bit line BL is formed in the first region 101 of the first deck structure 710, and the extending direction of the bit line BL intersects the first direction X. In an example, the bit line BL may extend in a Y-Z plane, for example, the extending direction of the bit line BL may be parallel to a third direction Z.

At S11, a second select gate is formed, wherein the second select gate is located on a side of the bit line facing away from the first select gate and is connected with the bit line.

In this operation, with continued reference to FIG. 46, the second select gate 262 is formed on the side of the bit line BL facing away from the first select gate 261, and is connected with the bit line BL.

At S12, a second deck structure is formed, wherein the second deck structure is located on a side of the second select gate away from the first deck structure, a first region of the second deck structure comprises a plurality of second sacrificial layers and a plurality of second dielectric layers stacked alternately along the first direction and adjoins a second region of the second deck structure, and the second region of the second deck structure is located on a side of the first region of the second deck structure along the second direction.

In this operation, with reference to FIG. 21, for example, the second dielectric layers 222 and the second sacrificial layers 721 may be alternately formed on the side of the second select gate 262 away from the first deck structure 710 using a deposition process. In an example, a material of the second dielectric layer 222 may include silicon oxide, and a material of the second sacrificial layer 721 may include silicon nitride.

According to the memory device 10 fabricated in this operation, its bit line BL is located between the first stack structure 210 and the second stack structure 220 and is connected with a channel structure in the first stack structure 210 and a channel structure in the second stack structure 220. Therefore, the bit line BL may drive the channel structure in the first stack structure 210 upwards, and meanwhile drive the channel structure in the second stack structure 220 downwards. Compared with the bit line BL being formed on the second stack structure 220, in this example, the bit line BL is formed between the first stack structure 210 and the second stack structure 220, which is favorable to increase the current intensity in the channel structure in the first stack structure 210 and the channel structure in the second stack structure 220 and solve the problem that the current intensity in part of the channel structure away from the bit line BL is weak.

In some examples, with reference FIG. 33, after forming the first deck structure 710 and before forming the second deck structure 720, the fabrication method further comprises: removing part of the first deck structure 710 to form a first connection hole 712, wherein the first connection hole 712 is located in the second region 102 of the first deck structure 710. For example, part of the first deck structure 710 may be removed using an etching process.

After forming the second deck structure 720, the fabrication method further comprises: removing part of the second deck structure 720 to form a second connection hole 722, wherein the second connection hole 722 is located in the second region 102 of the second deck structure 720, and the second connection hole 722 and the first connection hole 712 jointly constitute a connection hole 730. For example, part of the second deck structure 720 may be removed using an etching process.

After forming the connection hole 730, with reference to FIGS. 33 and 37, the fabrication method further comprises: replacing the first sacrificial layer 711 with the first gate layer 211 and replacing the second sacrificial layers 721 with the second gate layers 221. A first connection structure 230 is formed in the connection hole 730, and is connected with at least one first gate layer 211 and at least one second gate layer 221.

In this operation, the first connection structure 230 may be formed in the connection hole 730 using one or more thin film deposition processes including but not limited to PVD, CVD and ALD.

According to the memory device 10 fabricated by the above fabrication method, one SD device may be connected with at least one first gate layer 211 and at least one second gate layer 221 through the first connection structure 230. One first gate layer 211 and one second gate layer 221 may share one first connection structure 230 and may share one SD device, which is favorable to control the footprint of the second region 102 and increase the storage density.

With reference to FIGS. 2, 3 and 8, some examples of the present disclosure further provide a memory system 1000 which comprises a controller 20 and the memory device 10 provided in some examples above (or the memory device 10 formed by the fabrication method of the memory device provided in some examples above), wherein the controller 20 is connected with the memory device 10. In an example, the controller 20 may be configured to manage data stored in the memory device 10, and communicated with an external apparatus (e.g., a host); or the controller 20 may be also configured to control operations, such as read, erase and program operations, of the memory device 10; or the controller 20 may be also configured to manage various functions with respect to data stored or to be stored in the memory device 10. The memory system 1000 may be integrated into various types of storage apparatuses, which may be referred to some examples above and is no longer repeated herein.

With reference to FIGS. 1, 2 and 8, some examples of the present disclosure further provide an electronic apparatus 3000 which comprises a mainboard 2000 and the memory system 1000 provided in the above examples. The type of the electronic apparatus 3000 may be referred to some examples above, which is no longer repeated herein.

In this example, the memory device 1000 comprises the memory device 10 provided in some examples above (or the memory device 10 formed by the fabrication method of the memory device provided in some examples above). In the memory device 10 provided in some examples above, the plurality of gate layers are led out to be connected with an SD device through one first connection structure 230, and the plurality of gate layers may share one SD device, which is favorable to increase the storage density of the memory device 10 so as to increase the storage density of the memory system 1000, and is favorable to increase internal memory of the electronic apparatus 3000 and to the development of the electronic apparatus 3000 towards miniaturization.

The above descriptions are merely particular implementations of the present disclosure, and the protection scope of the present disclosure is not limited to those. Any variation or replacement that may be readily figured out by those skilled in the art within the technical scope disclosed by the present disclosure shall be encompassed within the protection scope of the present disclosure. Therefore, the scope of protection of the present disclosure should be defined by the scope of protection of the claims.

What is claimed is:

1. A fabrication method of a memory device, comprising:
forming a first stack structure comprising a plurality of first gate layers and a plurality of first dielectric layers stacked alternately along a first direction;
forming a second stack structure comprising a plurality of second gate layers and a plurality of second dielectric layers stacked alternately along the first direction, wherein the second stack structure and the first stack structure are stacked along the first direction;
forming a first connection structure that is located on a side of the first stack structure and the second stack structure along a second direction and is connected with at least one of the plurality of first gate layers and at least one of the plurality of second gate layers, wherein the second direction intersects the first direction; and
forming a bit line located between the first stack structure and the second stack structure, wherein an extending direction of the bit line intersects the first direction.

2. The fabrication method of claim 1, wherein forming the first stack structure comprises:
forming a first deck structure, wherein a first region of the first deck structure comprises a plurality of first sacrificial layers and a plurality of first dielectric layers stacked alternately along the first direction and adjoins a second region of the first deck structure, the second region of the first deck structure is located on a side of the first region of the first deck structure along the second direction, and the second direction intersects the first direction;
forming the second stack structure comprises:
forming a second deck structure located on a side of the bit line away from the first deck structure, wherein a first region of the second deck structure comprises a plurality of second sacrificial layers and a plurality of second dielectric layers stacked alternately along the first direction and adjoins a second region of the second deck structure, and the second region of the second deck structure is located on a side of the first region of the second deck structure along the second direction;
after forming the first deck structure and before forming the second deck structure, the fabrication method comprises:
removing part of the first deck structure to form a first connection hole that is located in the second region of the first deck structure;
after forming the second deck structure and before forming the first connection structure, the fabrication method comprises:
removing part of the second deck structure to form a second connection hole that is located in the second region of the second deck structure, wherein the second connection hole and the first connection hole jointly constitute a connection hole;
after forming the second deck structure and before forming the first connection structure, the fabrication method further comprises:
replacing the plurality of first sacrificial layers with the plurality of first gate layers, and
replacing the plurality of second sacrificial layers with the second gate layers; and
forming the first connection structure comprises:
depositing a conductive material in the connection hole to form the first connection structure.

3. The fabrication method of claim 2, wherein after forming the first deck structure and before removing part of the first deck structure, the fabrication method further comprises:
forming a first groove that is located in the second region of the first deck structure and extends through part of the first deck structure along the first direction, wherein the second region of the first deck structure comprises a plurality of third dielectric layers and a plurality of fourth dielectric layers stacked alternately along the first direction, and at least one of the plurality of third dielectric layers is connected with the first sacrificial layer;
forming a first connection sacrificial layer that covers a bottom of the first groove and is in contact with the third dielectric layer; and
forming a first isolation layer that is located in the first groove.

4. The fabrication method of claim 3, wherein forming the first connection sacrificial layer comprises:
forming a first isolation sub-layer that covers a wall of the first groove;
depositing a dielectric material in the first groove, wherein the dielectric material covers the bottom of the first groove; and
performing ion implantation on the dielectric material to form the first connection sacrificial layer; and
forming the first isolation layer comprises:
forming a second isolation sub-layer in the first groove, wherein the second isolation sub-layer and the first isolation sub-layer jointly constitute the first isolation layer.

5. The fabrication method of claim 3, wherein removing part of the first deck structure comprises:
removing the first isolation layer, the first connection sacrificial layer, and the plurality of third dielectric layers and the plurality of fourth dielectric layers that are stacked together, to form the first connection hole.

6. The fabrication method of claim 3, wherein after forming the second deck structure and before removing part of the second deck structure, the fabrication method further comprises:
forming a second groove that is located in the second region of the second deck structure and extends through part of the second deck structure along the first direction, wherein the second region of the second deck structure comprises a plurality of fifth dielectric layers and a plurality of sixth dielectric layers stacked alternately along the first direction, and at least one of the plurality of fifth dielectric layers is connected with the second sacrificial layer;
forming a second connection sacrificial layer that covers a bottom of the second groove and is in contact with the fifth dielectric layer; and
forming a second isolation layer that is located in the second groove; and
removing part of the second deck structure comprises:
removing the second isolation layer, the second connection sacrificial layer, and the plurality of fifth dielectric layers and the plurality of sixth dielectric layers that are stacked together, to form the second connection hole.

7. The fabrication method of claim 6, wherein forming the first connection structure in the connection hole comprises:
removing the first connection sacrificial layer and the second connection sacrificial layer to form a first recessed space and a second recessed space, wherein the first recessed space and the first connection hole are connected, and the second recessed space and the second connection hole are connected;
removing the third dielectric layers exposed to the first recessed space and the fifth dielectric layers exposed to the second recessed space, to form a first filling space and a second filling space, wherein the first filling space and the first recessed space are connected, and the second filling space and the second recessed space are connected; and
filling a conductive material in the connection hole to form the first connection structure.

8. The fabrication method of claim 7, wherein removing the first connection sacrificial layer and the second connection sacrificial layer further comprises:
removing part of the third dielectric layers and part of the fifth dielectric layers to form a third recessed space and a fourth recessed space, wherein the third recessed space and the first connection hole are connected, and the fourth recessed space and the second connection hole are connected; and
forming a third isolation layer in the third recessed space, and forming a fourth isolation layer in the fourth recessed space.

9. The fabrication method of claim 2, wherein after forming the first deck structure and before removing part of the first deck structure, the fabrication method further comprises:
forming a third groove that is located in the second region of the first deck structure and extends through part of the first deck structure along the first direction, wherein the second region of the first deck structure comprises a plurality of third dielectric layers and fourth dielectric layers stacked alternately along the first direction, and at least one of the plurality of third dielectric layers is connected with the first sacrificial layer;
forming a first isolation sub-layer that covers a wall of the third groove;
forming a second isolation sub-layer, wherein the second isolation sub-layer covers a bottom of the third groove, is in contact with the third dielectric layer, and covers a side of the first isolation sub-layer; and
forming a third isolation sub-layer in the third groove, wherein the third isolation sub-layer covers the second isolation sub-layer, and the first isolation sub-layer, the second isolation sub-layer and the third isolation sub-layer jointly constitute a first isolation layer.

10. The fabrication method of claim 9, wherein removing part of the first deck structure comprises:
removing the second isolation sub-layer, the third isolation sub-layer, the plurality of third dielectric layers and the plurality of fourth dielectric layers to form the first connection hole.

11. The fabrication method of claim 10, wherein after forming the second deck structure and before removing part of the second deck structure, the fabrication method further comprises:
forming a fourth groove that is located in the second region of the second deck structure and extends through part of the second deck structure along the first direction, wherein the second region of the second deck structure comprises a plurality of fifth dielectric layers and a plurality of sixth dielectric layers stacked alternately along the first direction, and at least one of the plurality of fifth dielectric layers is connected with the second sacrificial layer;
forming a fourth isolation sub-layer that covers a wall of the fourth groove;
forming a fifth isolation sub-layer that covers a bottom of the fourth groove and the fourth isolation sub-layer and is in contact with the fifth dielectric layer; and
forming a sixth isolation sub-layer in the fourth groove, wherein the sixth isolation sub-layer covers the fifth isolation sub-layer, and the fourth isolation sub-layer, the fifth isolation sub-layer and the sixth isolation sub-layer jointly constitute a second isolation layer; and
removing part of the second deck structure comprises:
removing the fifth isolation sub-layer, the sixth isolation sub-layer, the plurality of fifth dielectric layers and the plurality of sixth dielectric layers to form the second connection hole.

12. The fabrication method of claim 11, wherein forming the first connection structure in the connection hole comprises:
removing the second isolation sub-layer at the bottom of the third groove and the fifth isolation sub-layer at the bottom of the fourth groove to form a fifth recessed space and a sixth recessed space, wherein the fifth recessed space and the first connection hole are connected, and the sixth recessed space and the second connection hole are connected;
removing the third dielectric layers exposed to the fifth recessed space and the fifth dielectric layers exposed to the sixth recessed space, to form a third filling space and a fourth filling space, wherein the third filling space and the fifth recessed space are connected, and the fourth filling space and the sixth recessed space are connected; and
filling a conductive material in the connection hole to form the first connection structure.

13. The fabrication method of claim 12, wherein removing the second isolation sub-layer at the bottom of the third groove and the fifth isolation sub-layer at the bottom of the fourth groove comprises:
removing part of the second dielectric layers and part of the fourth dielectric layers to form a seventh recessed space and an eighth recessed space, wherein the seventh recessed space and the first connection hole are connected, and the eighth recessed space and the second connection hole are connected; and
forming a third isolation layer in the seventh recessed space, and forming a fourth isolation layer in the eighth recessed space.

14. The fabrication method of claim 1, wherein removing part of the first deck structure to form the first connection hole further comprises:
forming a first gate slit that is located in the first region of the first deck structure;
removing part of the second deck structure to form the second connection hole further comprises:
forming a second gate slit that is located in the first region of the second deck structure, wherein the second gate slit and the first gate slit jointly constitute a gate slit; and
replacing the first plurality of sacrificial layers with the plurality of first gate layers and replacing the second plurality of sacrificial layers with the plurality of second gate layers comprises:
injecting an etchant into the gate slit to remove the first plurality of sacrificial layers and
the plurality of second sacrificial layers, to form a fifth filling space and a sixth filling space; and
depositing a gate material in the fifth filling space and the sixth filling space to form the plurality of first gate layers and the plurality of second gate layers.

15. The fabrication method of claim 14, wherein forming the first deck structure comprises:
forming a first deck sub-structure that comprises a first gate sub-slit and a first channel hole;
forming an etching stop layer on the first gate sub-slit and the first channel hole; and
forming a second deck sub-structure that is located on a side of the etching stop layer away from the first gate sub-slit and the first channel hole, wherein the second deck sub-structure and the first deck sub-structure jointly constitute the first deck structure; and
removing part of the first deck structure to form the first connection hole comprises:
forming a second gate sub-slit and a second channel hole, wherein the second gate sub-slit and the first gate sub-slit jointly constitute the first gate slit, the second channel hole and the first channel hole jointly constitute a channel hole, and the first gate slit and the channel hole are located in the first region of the first deck structure.

16. A fabrication method of a memory device, comprising:
forming a first stack structure comprising a plurality of first gate layers and a plurality of first dielectric layers stacked alternately along a first direction;
forming a second stack structure comprising a plurality of second gate layers and a plurality of second dielectric layers stacked alternately along the first direction, wherein the second stack structure and the first stack structure are stacked along the first direction; and
forming a first connection structure, the first connection structure comprising a connection pillar, at least one first connection layer and at least one second connection layer, wherein the connection pillar is located on a side of the first stack structure and the second stack structure along a second direction; the first connection layer is parallel to the second direction; one first connection layer is connected with the connection pillar and one of the plurality of first gate layers; the second connection layer is parallel to the second direction; one second connection layer is connected with the connection pillar and one of the plurality of second gate layers; and the second direction intersects the first direction.

17. The fabrication method of claim 16, wherein forming the first stack structure comprises:
forming a first deck structure, wherein a first region of the first deck structure comprises a plurality of first sacrificial layers and a plurality of first dielectric layers stacked alternately along the first direction and adjoins a second region of the first deck structure, the second region of the first deck structure is located on a side of the first region of the first deck structure along the second direction, and the second direction intersects the first direction;
forming the second stack structure comprises:
forming a second deck structure, wherein the second deck structure and the first deck structure are stacked along the first direction; a first region of the second deck structure comprises a plurality of second sacrificial layers and a plurality of second dielectric layers stacked alternately along the first direction; the first region of the second deck structure adjoins a second region of the second deck structure; and the second region of the second deck structure is located on a side of the first region of the second deck structure along the second direction;
after forming the first deck structure and before forming the second deck structure, the fabrication method further comprises:
removing part of the first deck structure to form a first connection hole that is located in the second region of the first deck structure;
removing part of the second deck structure to form a second connection hole that extends through the second region of the second deck structure, wherein the second connection hole and the first connection hole jointly constitute a connection hole;
forming a first filling space and a second filling space, wherein the first filling space is located in the second region of the first deck structure, the first filling space and the first connection hole are connected, the second filling space is located in the second region of the first deck structure, and the second filling space and the second connection hole are connected; and
replacing the plurality of first sacrificial layers with the plurality of first gate layers, and replacing the second plurality of sacrificial layers with the second plurality of gate layers; and
forming the first connection structure comprises:
filling a conductive material in the connection hole to form the first connection structure, wherein the conductive material filled in the connection hole forms the connection pillar; the conductive material filled in the first filling space forms the first connection layer; the conductive material filled in the second filling space forms the second connection layer; the first connection layer is parallel to the second direction; one first connection layer is connected with the connection pillar and one of the plurality of first gate layers; the second connection layer is parallel to the second direction; one second connection layer is connected with the connection pillar and one of the plurality of second gate layers; and the connection pillar, the first connection layer and the second connection layer jointly constitute the first connection structure.

18. A fabrication method of a memory device, comprising:
forming a first deck structure, wherein a first region of the first deck structure comprises a plurality of first sacrificial layers and a plurality of first dielectric layers stacked alternately along a first direction and adjoins a second region of the first deck structure, the second region of the first deck structure is located on a side of the first region of the first deck structure along a second direction, and the second direction intersects the first direction;
forming a first select gate that is located in the first region of the first deck structure;
forming a bit line in the first region of the first deck structure, wherein the bit line is connected with the first select gate, and an extending direction of the bit line intersects the first direction;
forming a second select gate that is located on a side of the bit line facing away from the first select gate and is connected with the bit line; and
forming a second deck structure located on a side of the second select gate away from the first deck structure, wherein a first region of the second deck structure comprises a plurality of second sacrificial layers and a plurality of second dielectric layers stacked alternately along the first direction and adjoins a second region of the second deck structure, and the second region of the second deck structure is located on a side of the first region of the second deck structure along the second direction.

19. The fabrication method of claim 18, wherein
after forming the first deck structure and before forming the second deck structure, the fabrication method further comprises:
removing part of the first deck structure to form a first connection hole that is located in the second region of the first deck structure;
after forming the second deck structure, the fabrication method further comprises:
removing part of the second deck structure to form a second connection hole that is located in the second region of the second deck structure, wherein the second connection hole and the first connection hole jointly constitute a connection hole;
replacing the plurality of first sacrificial layers with a plurality of first gate layers, and replacing the second plurality of sacrificial layers with a plurality of second gate layers; and
forming a first connection structure in the connection hole, wherein the first connection structure is connected with at least one of the plurality of first gate layers and is connected with at least one of the plurality of second gate layers.
